(19) United States
(12) Patent Application Publication
(10) Pub. No.: US 2015/0070600 A1
(43) Pub. Date: Mar. 12, 2015

(54) SENSOR DEVICE, METHOD OF MANUFACTURING SENSOR DEVICE, DISPLAY APPARATUS, AND INPUT APPARATUS

(71) Applicant: Sony Corporation, Tokyo (JP)

(72) Inventors: Hiroto KAWAGUCHI, Kanagawa (JP); Fumihiko IIDA, Kanagawa (JP); Tomoaki SUZUKI, Kanagawa (JP); Takayuki TANAKA, Kanagawa (JP); Shogo SHINKAI, Kanagawa (JP); Hayato HASEGAWA, Kanagawa (JP); Tomoko KATSUHARA, Kanagawa (JP); Taizo NISHIMURA, Kanagawa (JP); Hiroshi MIZUNO, Kanagawa (JP); Yasuyuki ABE, Kanagawa (JP)

(21) Appl. No.: 14/476,124

(22) Filed: Sep. 3, 2014

(30) Foreign Application Priority Data
Sep. 10, 2013 (JP) 2013-187592

(51) Int. Cl. G01R 33/09; B32B 37/12; B32B 37/18; G06F 3/044

(52) U.S. Cl. CPC G01R 33/09; G06F 3/044; B32B 37/12; B32B 37/18; B32B 2457/00
USPC 349/12; 324/244; 156/60

(57) ABSTRACT

A sensor device includes: a first base material and a second base material disposed apart to face each other; a plurality of first adhesion sections that are two-dimensionally arranged in a gap between the first base material and the second base material and have elasticity; and a mitigation section configured to mitigate an increase in contact area of each of the first adhesion sections to one of the first base material and the second base material, the contact area increasing as the gap narrows.

### CROSS REFERENCES TO RELATED APPLICATIONS

The present application claims priority to Japanese Priority Patent Application JP2013-187592 filed in the Japan Patent Office on Sep. 10, 2013, the entire content of which is hereby incorporated by reference.

### BACKGROUND

The present application relates to a sensor device, and a method of manufacturing the sensor device, as well as a display apparatus and an input apparatus each including the sensor device.

In recent years, portable information processing apparatuses represented by mobile phones have been made multifunctional, and many kinds of configurations in which a display section serves as a user interface have been proposed. For example, Japanese Unexamined Patent Application Publication No. 2011-170659 (JP2011-170659A) has proposed a sensor including a capacitor and capable of detecting an operated position and pressing force of an operation member, on an input operation surface. In JP2011-170659A, an elastic body is provided as an adhesive material between electrodes, so that capacity is changed by the pressing force.

### SUMMARY

In general, an adhesive material has low elasticity, and deforms somewhat easily. Therefore, when the adhesive material is squashed by large pressure, it may take a considerably long time for the adhesive material to return to the original shape after unloading. In this case, a response speed of the sensor may decrease, which is disadvantageous.

It is desirable to provide a sensor device capable of reducing a decline in response speed, a method of manufacturing the sensor device, as well as a display apparatus and an input apparatus each including such a sensor device.

According to an embodiment of the present application, there is provided a sensor device including: a first base material and a second base material disposed apart to face each other; a plurality of first adhesion sections that are two-dimensionally arranged in a gap between the first base material and the second base material and have elasticity; and a mitigation section configured to mitigate an increase in contact area of each of the first adhesion sections to one of the first base material and the second base material, the contact area increasing as the gap narrows.

According to an embodiment of the present application, there is provided a display apparatus including: a display panel having a display surface; and a sensor device disposed on a side, opposite to the display surface, of the display panel, wherein the sensor device includes a first base material and a second base material disposed apart to face each other, a plurality of first adhesion sections that are two-dimensionally arranged in a gap between the first base material and the second base material and have elasticity, and a mitigation section configured to mitigate an increase in contact area of each of the first adhesion sections to one of the first base material and the second base material, the contact area increasing as the gap narrows.

According to an embodiment of the present application, there is provided an input apparatus including: a substrate having an operation surface; and a sensor device disposed on a side, which is opposite to the operation surface, of the substrate, wherein the sensor device includes a first base material and a second base material disposed apart to face each other, a plurality of first adhesion sections that are two-dimensionally arranged in a gap between the first base material and the second base material and have elasticity, and a mitigation section configured to mitigate an increase in contact area of each of the first adhesion sections to one of the first base material and the second base material, the contact area increasing as the gap narrows.

In the sensor device, the display apparatus, and the input apparatus according to the above-described embodiments of the present application, the mitigation section is provided. The mitigation section is configured to mitigate an increase in the area of contact between the first base material and the second base material, the area increasing as the gap between the first base material and the second base material narrows. This suppresses an increase in adhesion strength between each of the first adhesion sections and the first base material or the second base material when the gap between the first base material and the second base material is narrowed, as compared with a case in which the mitigation section is not provided.

According to an embodiment of the present application, there is provided a method of manufacturing a sensor device, the method including: increasing viscosity of each of a plurality of first adhesion sections, after printing, on a surface of a first base material, the first adhesion sections that are two-dimensionally arranged; providing a mitigation section on a surface of the first base material or a second base material, the mitigation section being configured to mitigate an increase in contact area of each of the first adhesion sections to one of the first base material and the second base material, the contact area increasing as a gap between the first base material and the second base material narrows, when the first base material and the second base material are adhered to each other, with each of the first adhesion sections interposed therebetween; and adhering the first base material and the second base material to each other, with each of the first adhesion sections interposed therebetween.

In the method of manufacturing the sensor device according to the above-described embodiment of the present application, the mitigation section is provided. The mitigation section is configured to mitigate an increase in the contact area of each of the first adhesion sections to one of the first base material and the second base material, the contact area increasing as the gap between the first base material and the second base material narrows. This suppresses an increase in adhesion strength between each of the first adhesion sections and the first base material or the second base material when the gap between the first base material and the second base material is narrowed, as compared with a case in which the mitigation section is not provided.

According to the sensor device, the method of manufacturing the sensor device, the display apparatus, and the input apparatus of the above-described embodiments of the present application, an increase in the above-described adhesion strength is suppressed. Therefore, it is possible to reduce time from unloading to returning of each of the first adhesion sections to the original shape. As a result, a decline in the response speed is allowed to be reduced. It is to be noted that effects of an embodiment of the present application are not necessarily limited to the effect described herein, and may be any of effects described in the present specification.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the present application, and are incorporated in and constitute a part of this specification. The drawings illustrate embodiments and, together with the specification, serve to describe the principles of the technology.

FIG. 1 is a diagram illustrating an example of a cross-sectional configuration of a display apparatus according to a first embodiment of the present application.

FIG. 2 is a diagram illustrating an example of a cross-sectional configuration of the sensor device of FIG. 1, together with a schematic configuration of a drive unit.

FIG. 3 is a diagram illustrating an example of a perspective configuration of the sensor device of FIG. 2.

FIG. 4 is a diagram illustrating an example of function of the display apparatus.

FIG. 5 is a diagram illustrating another example of the function of the display apparatus.

FIG. 6A is an enlarged view illustrating an example of a cross-sectional configuration of an adhesion section and a neighborhood thereof in the sensor device of FIG. 2.

FIG. 6B is a diagram illustrating an example of an area of a contact part between an upper insulating layer and the adhesion section in FIG. 6A.

FIG. 7A is an enlarged view illustrating an example of a cross-sectional configuration of an adhesion section and a neighborhood thereof in the sensor device of FIG. 2.

FIG. 7B is a diagram illustrating an example of an area of a contact part between an upper insulating layer and the adhesion section in FIG. 7A.

FIG. 8A is a diagram illustrating an example of a shape change of the adhesion section when the upper insulating layer of FIG. 6A is pressed.

FIG. 8B is a diagram illustrating an example of an area of a contact part between the upper insulating layer and the adhesion section in FIG. 8A.

FIG. 9A is a diagram illustrating an example of a shape change of the adhesion section when the upper insulating layer of FIG. 7A is pressed.

FIG. 9B is a diagram illustrating an example of the area of the contact part between the upper insulating layer and the adhesion section in FIG. 9A.

FIG. 10A is a diagram illustrating an example of a process in a method of manufacturing the sensor device.

FIG. 10B is a diagram illustrating an example of a process following the process in FIG. 10A.

FIG. 10C is a diagram illustrating an example of a process following the process in FIG. 10B.

FIG. 11 is a diagram illustrating an example of an apparatus evaluating a response speed of the sensor device.

FIG. 12 is a diagram illustrating another example of the apparatus evaluating the response speed of the sensor device.

FIG. 13 is a diagram illustrating an example of a response characteristic of the sensor device, together with a response characteristic of a sensor device according to a comparative example.

FIG. 14A is a diagram illustrating an example of a cross-sectional configuration of the sensor device according to the comparative example.

FIG. 14B is a diagram illustrating an example of an area of a contact part between an upper insulating layer and an adhesion section in FIG. 14A.

FIG. 15A is a diagram illustrating an example of a shape change of the adhesion section when the upper insulating layer of FIG. 14A is pressed.

FIG. 15B is a diagram illustrating an example of the area of the contact part between the upper insulating layer and the adhesion section in FIG. 15A.

FIG. 16A is an enlarged view illustrating a modification of the cross-sectional configuration of the adhesion section and the neighborhood thereof in the sensor device.

FIG. 16B is a diagram illustrating an example of the area of the contact part between the upper insulating layer and the adhesion section in FIG. 16A.

FIG. 17A is a diagram illustrating an example of a shape change of the adhesion section when the upper insulating layer of FIG. 16A is pressed.

FIG. 17B is a diagram illustrating an example of the area of the contact part between the upper insulating layer and the adhesion section in FIG. 17A.

FIG. 18A is an enlarged view illustrating a modification of the cross-sectional configuration of the adhesion section and the neighborhood thereof in the sensor device.

FIG. 18B is a diagram illustrating an example of the area of the contact part between the upper insulating layer and the adhesion section in FIG. 18A.

FIG. 19A is a diagram illustrating an example of a shape change of the adhesion section when the upper insulating layer of FIG. 18A is pressed.

FIG. 19B is a diagram illustrating an example of the area of the contact part between the upper insulating layer and the adhesion section in FIG. 19A.

FIG. 20 is a diagram illustrating an example of a process in a method of manufacturing the sensor device having a configuration of FIG. 18A.

FIG. 21A is a diagram illustrating an example of a plane configuration of a annular body of FIG. 20.

FIG. 21B is a diagram illustrating an example of a plane configuration of the annular body of FIG. 20.

FIG. 22A is a diagram illustrating an example of a process following the process in FIG. 20.

FIG. 22B is a diagram illustrating an example of a process following the process in FIG. 22A.

FIG. 22C is a diagram illustrating an example of a process following the process in FIG. 22B.

FIG. 23 is an enlarged view illustrating a modification of the cross-sectional configuration of the adhesion section and the neighborhood thereof in the sensor device.

FIG. 24A is a diagram illustrating an example of a process in a method of manufacturing the sensor device having a configuration of FIG. 23.

FIG. 24B is a diagram illustrating an example of a process following the process in FIG. 24A.

FIG. 24C is a diagram illustrating an example of a process following the process in FIG. 24B.

FIG. 24D is a diagram illustrating an example of a process following the process in FIG. 24C.

FIG. 25 is an enlarged view illustrating a modification of the cross-sectional configuration of the adhesion section and the neighborhood thereof in the sensor device.

FIG. 26A is an enlarged view illustrating a modification of the cross-sectional configuration of the adhesion section and the neighborhood thereof in the sensor device.

FIG. 26B is a diagram illustrating an example of the area of the contact part between the upper insulating layer and the adhesion section in FIG. 26A.

FIG. 27A is a diagram illustrating an example of a shape change of the adhesion section when the upper insulating layer of FIG. 26A is pressed.

FIG. 27B is a diagram illustrating an example of the area of the contact part between the upper insulating layer and the adhesion section in FIG. 27A.

FIG. 28 is a diagram illustrating an example of a process in a method of manufacturing the sensor device having a configuration of FIG. 26A.

FIG. 29A is a diagram illustrating an example of a plane configuration of a projection of FIG. 28.

FIG. 29B is a diagram illustrating an example of a plane configuration of the projection of FIG. 28.

FIG. 30A is a diagram illustrating an example of a process following the process in FIG. 28.

FIG. 30B is a diagram illustrating an example of a process following the process in FIG. 30A.

FIG. 30C is a diagram illustrating an example of a process following the process in FIG. 30B.

FIG. 31 is an enlarged view illustrating a modification of the cross-sectional configuration of the adhesion section and the neighborhood thereof in the sensor device.

FIG. 32A is an enlarged view illustrating a modification of the cross-sectional configuration of the adhesion section and the neighborhood thereof in the sensor device.

FIG. 32B is a diagram illustrating an example of an area of a contact part between the upper insulating layer and the adhesion section in FIG. 32A.

FIG. 33A is a diagram illustrating an example of a shape change of the adhesion section when the upper insulating layer of FIG. 32A is pressed.

FIG. 33B is a diagram illustrating an example of the area of the contact part between the upper insulating layer and the adhesion section in FIG. 33A.

FIG. 34 is an enlarged view illustrating a modification of the cross-sectional configuration of the adhesion section and the neighborhood thereof in the sensor device.

FIG. 35 is a diagram illustrating a modification of the cross-sectional configuration of the sensor device of FIG. 2.

FIG. 36 is a diagram illustrating an example of a cross-sectional configuration of an input apparatus according to a second embodiment of the present application.

FIG. 37 is a diagram illustrating an example of a cross-sectional configuration of an input apparatus according to a third embodiment of the present application.

FIG. 38 is a diagram illustrating a modification of the cross-sectional configuration of the input apparatus of FIG. 37.

FIG. 39 is a diagram illustrating a specific but not limitative example of the cross-sectional configuration of the input apparatus of FIGS. 37 and 38.

FIG. 40 is a diagram illustrating a specific but not limitative example of the cross-sectional configuration of the input apparatus of FIGS. 37 and 38.

FIG. 41 is a diagram illustrating a modification of the cross-sectional configuration of the sensor device in each of the above-described embodiments.

FIG. 42A is an enlarged view illustrating an example of a cross-sectional configuration of an adhesion section and a neighborhood thereof in the sensor device of FIG. 41.

FIG. 42B is an enlarged view illustrating an example of a cross-sectional configuration of the adhesion section and the neighborhood thereof in the sensor device of FIG. 41.

FIG. 42C is an enlarged view illustrating an example of a cross-sectional configuration of the adhesion section and the neighborhood thereof in the sensor device of FIG. 41.

FIG. 42D is an enlarged view illustrating an example of a cross-sectional configuration of the adhesion section and the neighborhood thereof in the sensor device of FIG. 41.

FIG. 42E is an enlarged view illustrating an example of a cross-sectional configuration of the adhesion section and the neighborhood thereof in the sensor device of FIG. 41.

FIG. 42F is an enlarged view illustrating an example of a cross-sectional configuration of the adhesion section and the neighborhood thereof in the sensor device of FIG. 41.

FIG. 42G is an enlarged view illustrating an example of a cross-sectional configuration of the adhesion section and the neighborhood thereof in the sensor device of FIG. 41.

FIG. 42H is an enlarged view illustrating an example of a cross-sectional configuration of the adhesion section and the neighborhood thereof in the sensor device of FIG. 41.

FIG. 42I is an enlarged view illustrating an example of a cross-sectional configuration of the adhesion section and the neighborhood thereof in the sensor device of FIG. 41.

FIG. 43 is a diagram illustrating a modification of the cross-sectional configuration of the sensor device in each of the above-described embodiments.

FIG. 44A is an enlarged view illustrating an example of a cross-sectional configuration of an adhesion section and a neighborhood thereof in the sensor device of FIG. 43.

FIG. 44B is an enlarged view illustrating an example of a cross-sectional configuration of the adhesion section and the neighborhood thereof in the sensor device of FIG. 43.

FIG. 44C is an enlarged view illustrating an example of a cross-sectional configuration of the adhesion section and the neighborhood thereof in the sensor device of FIG. 43.

FIG. 44D is an enlarged view illustrating an example of a cross-sectional configuration of the adhesion section and the neighborhood thereof in the sensor device of FIG. 43.

FIG. 44E is an enlarged view illustrating an example of a cross-sectional configuration of the adhesion section and the neighborhood thereof in the sensor device of FIG. 43.

FIG. 44F is an enlarged view illustrating an example of a cross-sectional configuration of the adhesion section and the neighborhood thereof in the sensor device of FIG. 43.

FIG. 44G is an enlarged view illustrating an example of a cross-sectional configuration of the adhesion section and the neighborhood thereof in the sensor device of FIG. 43.

FIG. 44H is an enlarged view illustrating an example of a cross-sectional configuration of the adhesion section and the neighborhood thereof in the sensor device of FIG. 43.

FIG. 44I is an enlarged view illustrating an example of a cross-sectional configuration of the adhesion section and the neighborhood thereof in the sensor device of FIG. 43.

FIG. 45 is a diagram illustrating an example of a cross-sectional configuration of a passive device according to a fourth embodiment of the present application.

FIG. 46A is an enlarged view illustrating an example of a cross-sectional configuration of an adhesion section and a neighborhood thereof in the passive device of FIG. 45.

FIG. 46B is an enlarged view illustrating an example of a cross-sectional configuration of the adhesion section and the neighborhood thereof in the passive device of FIG. 45.

FIG. 46C is an enlarged view illustrating an example of a cross-sectional configuration of the adhesion section and the neighborhood thereof in the passive device of FIG. 45.

FIG. 46D is an enlarged view illustrating an example of a cross-sectional configuration of the adhesion section and the neighborhood thereof in the passive device of FIG. 45.

FIG. 46E is an enlarged view illustrating an example of a cross-sectional configuration of the adhesion section and the neighborhood thereof in the passive device of FIG. 45.

FIG. 46F is an enlarged view illustrating an example of a cross-sectional configuration of the adhesion section and the neighborhood thereof in the passive device of FIG. 45.

FIG. 46G is an enlarged view illustrating an example of a cross-sectional configuration of the adhesion section and the neighborhood thereof in the passive device of FIG. 45.

FIG. 46H is an enlarged view illustrating an example of a cross-sectional configuration of the adhesion section and the neighborhood thereof in the passive device of FIG. 45.

FIG. 46I is an enlarged view illustrating an example of a cross-sectional configuration of the adhesion section and the neighborhood thereof in the passive device of FIG. 45.

### DETAILED DESCRIPTION

Some embodiments of the present application will be described below in detail with reference to the drawings. It is to be noted that the description will be provided in the following order.

1. First embodiment (a display apparatus)

An example in which a mitigation section is provided in an upper insulating layer

2. Modifications of the first embodiment

Variations on the Mitigation Section

3. Second embodiment (an input apparatus)

An example in which a substrate is provided in place of a display panel in the display apparatus of the above-described first embodiment

4. Third embodiment (an input apparatus)

An example in which a key region is provided in the substrate in the above-described second embodiment

5. Variations on the sensor device

5.1 Magnetic-type sensor device

5.2 Resistance-type sensor device

6. Fourth embodiment (a passive device)

### 1. First Embodiment

### Configuration

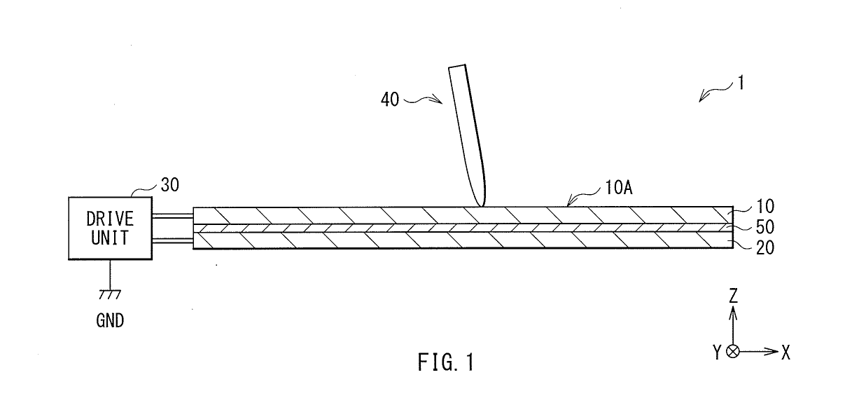

FIG. 1 illustrates an example of a cross-sectional configuration of a display apparatus 1 according to a first embodiment of the present application. The display apparatus 1 displays an image on a display surface 10A, and the display surface 10A serves as an operation surface. The display apparatus 1 may include, for example, a display panel 10, a sensor device 20, a drive unit 30, a pen 40, and a resin layer 50.

The display panel 10 displays an image on the display surface 10A, and may be, for example, a panel such as a liquid crystal panel, an organic electro-luminescence (EL) panel, and an electrophoretic panel. The display panel 10 has flexibility, and may include, for example, a flexible resin film or a flexible sheet glass. The sensor device 20 detects a contact position or a pressed position of an object such as the pen 40, on the display surface 10A, and outputs a detection result (a detection signal) to the drive unit 30. It is to be noted that the sensor device 20 will be described in detail later.

The drive unit 30 causes the display panel 10 to display an image on the display surface 10A, by applying a voltage to the display panel 10. Further, by applying a voltage to the sensor device 20, the drive unit 30 drives the sensor device 20, and receives the detection signal from the sensor device 20. Furthermore, the drive unit 30 generates a voltage based on the received detection signal, and causes a change in display on the display surface 10A by applying the generated voltage to the display panel 10. The drive unit 30 may generate an image signal based on the received detection signal, and may output the generated image signal to outside.

The pen 40 is caused to touch or press the display surface 10A. The sensor device 20 detects a contact position or a pressed position of the pen 40, on the display surface 10A. It is to be noted that the pen 40 may be omitted. In this case, a finger may be used in place of the pen 40.

The resin layer 50 is provided to adhere the display panel 10 and the sensor device 20 to each other. The resin layer 50 may be configured of, for example, a sheet-like, spot-like, grid-like, or stripes-like adhesive layer or bonding layer. Examples of a material of the resin layer 50 may include: an acryl-based adhesive; an ethylene-vinyl acetate copolymer; a natural-rubber-based adhesive; a synthetic-rubber-based adhesive such as polyisobutylene, a butyl rubber, a styrene-butylene-styrene copolymer, and a styrene-isoprene-styrene-block copolymer; a polyurethane-based adhesive; a polyester-based adhesive; an epoxy-based adhesive; and a silicon-based adhesive. The resin layer 50 may have, for example, a thickness of about 0.5 μm to about 500 μm.

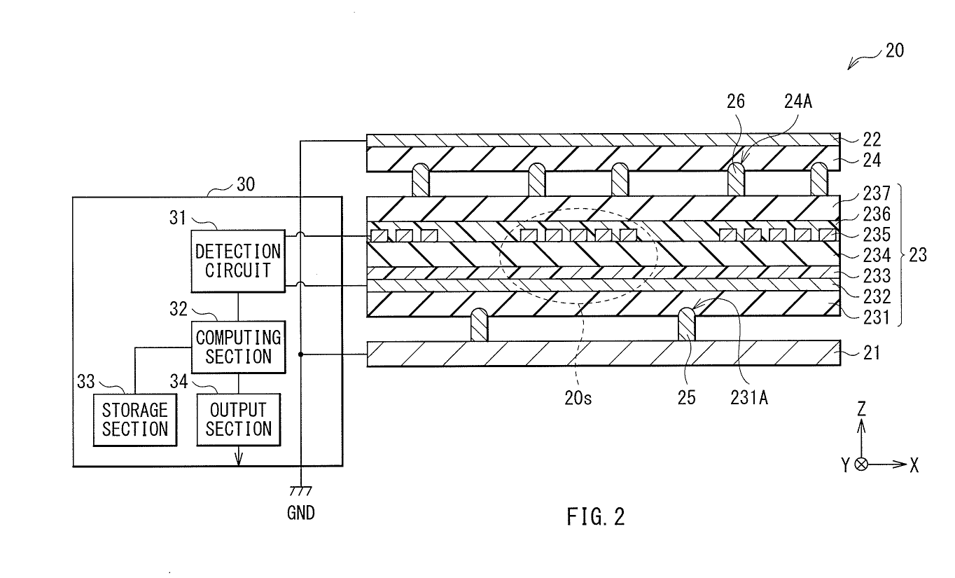

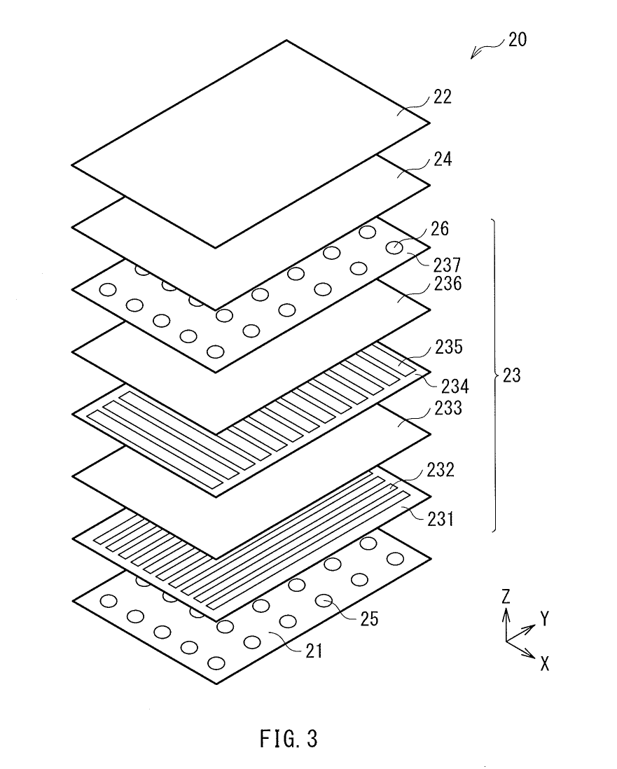

Next, the sensor device 20 will be described in detail. FIG. 2 illustrates an example of a cross-sectional configuration of the sensor device 20, together with a schematic configuration of the drive unit 30. FIG. 3 illustrates an example of a perspective configuration of the sensor device 20.

The sensor device 20 is disposed at a position facing a surface, which is opposite to the display surface 10A, of the display panel 10. In other words, the sensor device 20 is not disposed on the display surface 10A. The sensor device 20 detects a contact position or a pressed position of an object such as the pen 40, on the display panel 10. For example, the sensor device 20 may be of a capacity type, and may have a configuration in which an electrode substrate 23 is interposed between conductive layers 21 and 22 in an up-down direction.

The electrode substrate 23 and the conductive layer 22 have flexibility. The electrode substrate 23 may include, for example, an insulating layer 231, a lower electrode 232, a bonding layer 233, an insulating layer 234, an upper electrode 235, a bonding layer 236, and an insulating layer 237, in this order from a conductive layer 21 side. For example, the sensor device 20 may have a gap between the conductive layer 21 and the electrode substrate 23, and may have a plurality of adhesion sections 25 as a spacer that maintains this gap. The plurality of adhesion sections 25 are two-dimensionally arranged on a surface of the conductive layer 21. For example, the sensor device 20 may have, between the conductive layer 22 and the electrode substrate 23, an insulating layer 24 in contact with the conductive layer 22. Further, for example, the sensor device 20 may also have a gap between the insulating layer 24 and the electrode substrate 23, and may have a plurality of adhesion sections 26 as a spacer that maintains this gap. The plurality of adhesion sections 26 are two-dimensionally arranged on a surface of the insulating layer 237. When viewed in a thickness direction of the sensor device 20, the plurality of adhesion sections 25 and the plurality of adhesion sections 26 are arranged not to overlap each other. It is to be noted that, each of the adhesion sections 25 and 26 will be described in detail later. The conductive layer 21 or the insulating layer 237 is equivalent to a specific but not limitative example of “first base material” according to an embodiment of the present application. The insulating layer 231 or the insulating layer 24 is equivalent to a specific but not limitative example of “second base material” according to an embodiment of the present application. The adhesion section 25 is equivalent to a specific but not limitative example of “first adhesion section” according to an embodiment of the present application. The adhesion section 26 is also equivalent to a specific but not limitative example of “first adhesion section” according to an embodiment of the present application.

The conductive layers 21 and 22 each serve as a shield layer that prevents a variation in capacitance formed between the sensor device 20 and the outside from affecting inside of the sensor device 20. The conductive layers 21 and 22 are at a fixed potential, for example, a ground potential. The conductive layers 21 and 22 may be configured of, for example, a metal plate made of metal such as SUS and iron. This metal plate may have flexibility. The conductive layers 21 and 22 may also be configured, for example, by forming, on a film, a metallic thin film made of metal such as aluminum, or a film of carbon, carbon nanotube (CNT), indium tin oxide (ITO), indium zinc oxide (IZO), a nano-metal wire, a silver fine wire, or the like.

The lower electrode 232 is disposed at a position facing the conductive layer 21. The lower electrode 232 includes a plurality of partial electrodes extending in a predetermined direction (an X direction in FIG. 2). The upper electrode 235 is disposed at a position facing the conductive layer 22. The upper electrode 235 includes a plurality of partial electrodes extending in a direction (a Y direction in FIG. 2) orthogonal to the lower electrode 232. The lower electrode 232 and the upper electrode 235 may be configured, for example, by forming, on a film, a metallic thin film made of metal such as aluminum, or a film of carbon, CNT, ITO, IZO, a nano-metal wire, a silver fine wire, or the like.

The lower electrode 232 and the upper electrode 235 intersect each other when the sensor device 20 is viewed from a normal direction of the sensor device 20. In an intersection part between the lower electrode 232 and the upper electrode 235, a capacitor is formed using the lower electrode 232, the bonding layer 233, the insulating layer 234, and the upper electrode 235. This capacitor has a capacity that changes in response to a variation in capacitance according to a distance between the lower electrode 232 and the conductive layer 21, or a variation in capacitance according to a distance between the upper electrode 235 and the conductive layer 22. Therefore, the intersection part between the lower electrode 232 and the upper electrode 235 serves as a detection section 20s capable of detecting a change in the distance between the lower electrode 232 and the conductive layer 21, or a change in the distance between the upper electrode 235 and the conductive layer 22. The detection section 20s may be provided as each of a plurality of detection sections 20s that are two-dimensionally arranged in a plane. As illustrated in FIG. 2, the plurality of detection sections 20s may be positioned with uniform spacings in the plane, or may be positioned collectively in each predetermined region (for example, each region racing the adhesion sections 26).

The insulating layer 231 insulates and separates the conductive layer 21 and the lower electrode 232 from each other. The insulating layer 234 insulates and separates the lower electrode 232 and the upper electrode 235 from each other. The insulating layer 237 insulates and separates the upper electrode 235 and the conductive layer 22 from each other. The insulating layers 231, 234, 237, and 24 may each be configured of, for example, a resin film having an insulation property. The insulating layers 231, 234, 237, and 24 may also each be configured of, for example, a UV-curable or thermally-curable hard coating material or the like formed by screen printing. The insulating layers 231, 234, 237, and 24 may also each be fabricated, for example, by patterning a spin-coated photosensitive resin through photolithography. The bonding layer 233 bonds the lower electrode 232 and the insulating layer 234 together. The bonding layer 236 bonds the upper electrode 235 and the insulating layer 234 together. The bonding layers 233 and 236 may each be formed, for example, by curing a UV-curable resin or a thermosetting resin.

The drive unit 30 generates drawing data based on an output of the sensor device 20, and outputs the generated drawing data to the outside. As illustrated in FIG. 2, the drive unit 30 may have, for example, a detection circuit 31, a computing section 32, a storage section 33, and an output section 34.

For example, the detection circuit 31 may read a variation in capacitance of the sensor device 20, based on a change in an amount of a current flowing in the electrode substrate 23. The detection circuit 31 may have, for example, a switching element, a signal source, and a current-voltage conversion circuit. The switching element switches between a plurality of lower electrodes 232 each equivalent to the lower electrode 232 and a plurality of upper electrodes 235 each equivalent to the upper electrode 235, included in the electrode substrate 23. The signal source supplies an alternating current (AC) signal to the electrode substrate 23. The switching element may be, for example, a multiplexer. Each of a plurality of terminals provided on one end side of the multiplexer is connected to one end of each of the lower electrodes 232 and one end of each of the upper electrodes 235. One terminal provided on the other end side of the multiplexer is connected to the signal source and the current-voltage conversion circuit.

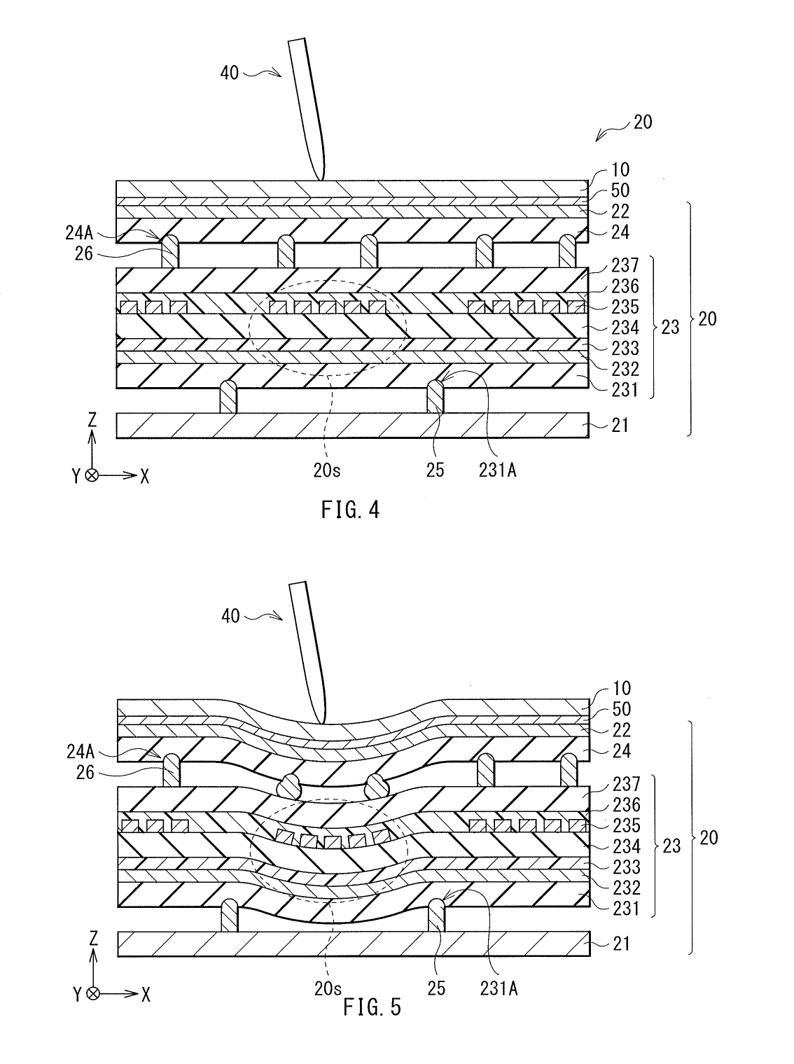

For example, the detection circuit 31 may select the plurality of lower electrodes 232 sequentially one by one, and may select the plurality of upper electrodes 235 sequentially one by one. The detection circuit 31 may thereby apply, for example, an AC signal to the plurality of lower electrodes 232 sequentially one by one, and to the plurality of upper electrodes 235 sequentially one by one. At this moment, for example, as illustrated in FIGS. 4 and 5, when the display surface 10A is touched or pressed by the pen 40, a variation in the capacitance of the electrode substrate 23 occurs, and this variation causes a change in the amount of a current flowing in the electrode substrate 23. For example, the detection circuit 31 may convert the change in the amount of the current into a voltage change, and may output this voltage change to the computing section 32. When the display surface 10A is touched by the pen 40, the electrode substrate 23 slightly deforms, which causes a variation in the capacitance of the electrode substrate 23. It is to be noted that FIG. 4 illustrates an example of a cross-sectional configuration of the sensor device 20 when the display surface 10A is touched by the pen 40. FIG. 5 illustrates an example of a cross-sectional configuration of the sensor device 20 when the display surface 10A is pressed by the pen 40.

The computing section 32 detects a contact or pressed position of the pen 40 in the display surface 10A, by evaluating the voltage change outputted from the detection circuit 31. Further, the computing section 32 derives the magnitude of a press of the pen 40 in the display surface 10A, by evaluating the voltage change outputted from the detection circuit 31. The computing section 32 generates drawing data by superimposing derived position data (postscript data generated based on an output of the sensor device 20) on drawing data stored in the storage section 33. The computing section 32 then stores the generated drawing data in the storage section 33, and outputs the generated drawing data to the output section 34. The storage section 33 stores the drawing data provided by the computing section 32. The output section 34 outputs the drawing data provided by the computing section 32, to the outside.

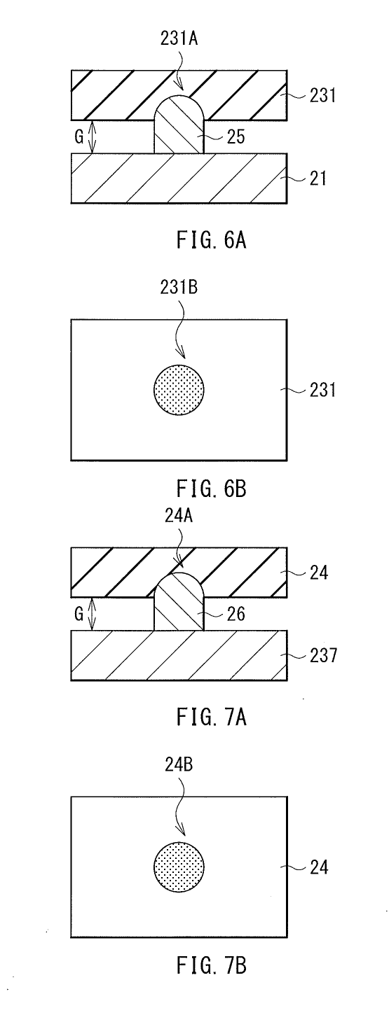

Next, each of the adhesion sections 25 and 26 as well as a peripheral configuration thereof will be described in detail. FIG. 6A illustrates an example of a cross-sectional configuration of the adhesion section 25 and a neighborhood thereof. FIG. 6B illustrates an example of an area of a contact part 231B between the insulating layer 231 and the adhesion section 25. FIG. 7A illustrates an example of a cross-sectional configuration of the adhesion section 26 and a neighborhood thereof. FIG. 7B illustrates an example of a contact part 24B between the insulating layer 24 and the adhesion section 26.

Each of the adhesion sections 25 is formed of an adhesive material having elasticity. Each of the adhesion sections 25 is in contact with the conductive layer 21 and the insulating layer 231. Of each of the adhesion sections 25, a top on the insulating layer 231 side is round, and may be shaped like, for example, a part of a sphere. The shape of this top may be formed, for example, by a method to be described later. The insulating layer 231 is shaped like a sheet, and has a depression 231A as a mitigation section at a position facing each of the adhesion sections 25. Here, the mitigation section refers to a section having a function of mitigating an increase in contact area of each of the adhesion sections 25 to the insulating layer 231. This area increases as a gap between the conductive layer 21 and the insulating layer 231 narrows.

The depression 231A may be, for example, formed by transferring the shape of a mold to a resin film. As with the adhesion section 25, an inner surface of the depression 231A is round, and may be shaped like, for example, a part of a sphere. Of the adhesion section 25, the top on the insulating layer 231 side is fitted into the depression 231A and is in contact with the inner surface of the depression 231A. Of the top on the insulating layer 231 side, an entire round part may be preferably fitted into the depression 231A. In this case, the area of the contact part 231B between the insulating layer 231 and the adhesion section 25 is substantially equal to an area of the inner surface of the depression 231A.

Each of the adhesion sections 26 is formed of an adhesive material having elasticity. Each of the adhesion sections 26 is in contact with the insulating layers 237 and 24. Of each of the adhesion sections 26, a top on the insulating layer 24 side is round, and may be shaped like, for example, a part of a sphere. The shape of this top may be formed, for example, by a method to be described later. The insulating layer 24 is shaped like a sheet, and has a depression 24A as a mitigation section at a position facing each of the adhesion sections 26. Here, the mitigation section refers to a section having a function of mitigating an increase in an area where each of the adhesion sections 26 is in contact with the insulating layer 24. This area increases as a gap between the insulating layers 237 and 24 narrows.

The depression 24A may be formed, for example, by transferring the shape of a mold to a resin film. As with the adhesion section 26, the depression 24A is round, and may be shaped like, for example, a part of a sphere. Of the adhesion section 26, the top on the insulating layer 24 side is fitted into the depression 24A and is in contact with an inner surface of the depression 24A. Of the top on the insulating layer 24 side, an entire round part may be preferably fitted into the depression 24A. In this case, the area of the contact part 24B between the insulating layer 24 and the adhesion section 26 is substantially equal to an area of the inner surface of the depression 24A.

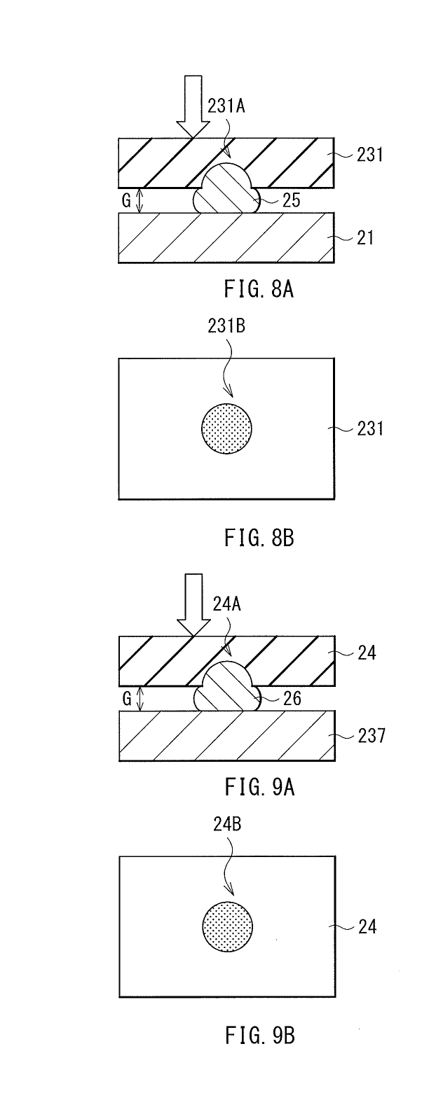

FIG. 8A illustrates an example of a shape change of the adhesion section 25 when the insulating layer 231 is pressed. FIG. 8B illustrates an example of the area of the contact part 231B between the insulating layer 231 and the adhesion section 25, when the insulating layer 231 is pressed. FIG. 9A illustrates an example of a shape change of the adhesion section 26 when the insulating layer 24 is pressed. FIG. 9B illustrates an example of the area of the contact part 24B between the insulating layer 24 and the adhesion section 26, when the insulating layer 24 is pressed.

When the insulating layer 231 is pressed, the adhesion section 25 is squashed by receiving pressure from the insulating layer 231 in a thickness direction. A gap G between the insulating layer 231 and the conductive layer 21 becomes narrower than the gap G before the pressing. Here, of the adhesion section 25, the top on the insulating layer 231 side is fitted into the depression 231A. Therefore, the area of the contact part 231B between the adhesion section 25 and the insulating layer 231 hardly differs from the area before the pressing, and the adhesion section 25 is flattened. Subsequently, upon being unloaded, the flattened adhesion section 25 returns to the original shape, by restoring force thereof.

When the insulating layer 24 is pressed, the adhesion section 26 is squashed by receiving pressure from the insulating layer 24 in a thickness direction. A gap G between the insulating layers 24 and 237 becomes narrower than the gap G before the pressing. Here, of the adhesion section 26, the top on the insulating layer 24 side is fitted into the depression 24A. Therefore, the area of the contact part 24B between the adhesion section 26 and the insulating layer 24 hardly differs from the area before the pressing, and the adhesion section 26 is flattened. Subsequently, upon being unloaded, the flattened adhesion section 26 returns to the original shape by restoring force thereof.

Each of the adhesion sections 25 is formed by printing on the surface of the conductive layer 21. Similarly, each of the adhesion sections 26 is formed by printing on the surface of the insulating layer 237. For example, each of the adhesion sections 25 and each of the adhesion sections 26 may be formed by printing a heat-sensitive adhesive material. The heat-sensitive adhesive material is then heated (or warmed), irradiated with ultraviolet rays, or cured by moisture, so that adhesiveness of the heat-sensitive adhesive material develops. Alternatively, each of the adhesion sections 25 and each of the adhesion sections 26 may be formed, for example, by printing an electron-beam sensitive adhesive material. The electron-beam sensitive adhesive material is then irradiated with an electron beam, so that adhesiveness of the electron-beam sensitive adhesive material develops. Here, the heat-sensitive adhesive material refers to a material in which adhesiveness is absent at ambient temperature, but the adhesiveness develops by heating (or warming), ultraviolet irradiation, or moisture curing. The heat-sensitive adhesive material may include, for example, crystal adhesive materials and tackifiers, and the adhesiveness may develop when the crystal is melted by heating (or warming). In addition, the electron-beam sensitive adhesive refers to a material in which adhesiveness is absent at ambient temperature, but the adhesiveness develops by molecular chain cutting caused by electron beam irradiation.

[Manufacturing Method]

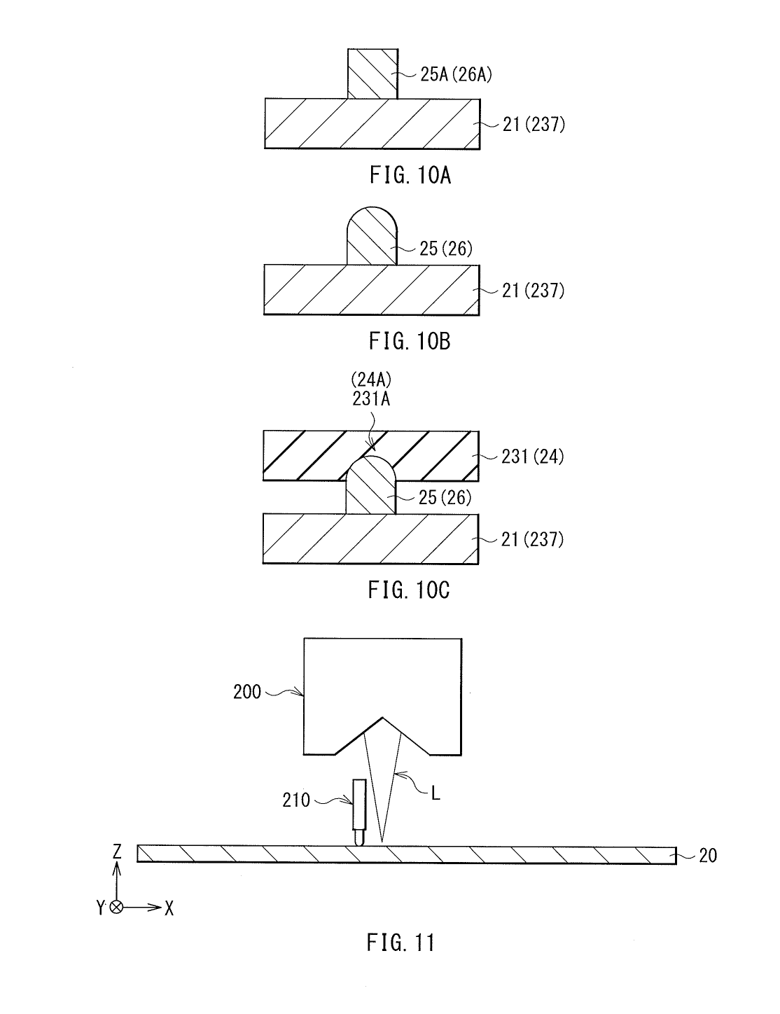

FIG. 10A illustrates an example of a process in a method of manufacturing the sensor device 20. FIG. 10B illustrates an example of a process following the process in FIG. 10A, and FIG. 10C illustrates an example of a process following the process in FIG. 10B. First, the plurality of adhesion sections 25A arranged two-dimensionally are printed on the surface of the conductive layer 21 (FIG. 10A). Similarly, the plurality of adhesion sections 26A arranged two-dimensionally are printed on the surface of the insulating layer 237 (FIG. 10A). The adhesion sections 25A and 26A may be formed, for example, of the heat-sensitive adhesive material or the electron-beam sensitive adhesive material, and have weak or no adhesive strength at this stage. It is to be noted that, in FIG. 10A, the adhesion sections 25A and 26A are each a rectangular parallelepiped, but the top of each of the adhesion sections 25A and 26A may be round to some degree, depending on the way of printing.

Next, a treatment of increasing viscosity of each of the adhesion sections 25A and 26A is performed. For example, the viscosity of each of the adhesion sections 25A and 26A may be increased by heating, ultraviolet irradiation, moisture curing, or electron beam irradiation, to form each of the adhesion sections 25 and 26. In this process, each of the adhesion sections 25 and 26 temporarily softens, and the top of each of the adhesion sections 25 and 26 becomes round due to surface tension (FIG. 10B). Subsequently, the insulating layer 231, in which the depression 231A serving as the mitigation section is formed, and the conductive layer 21 are adhered to each other, with the adhesion section 25 interposed therebetween (FIG. 10C). In this process, the top of the adhesion section 25 is fitted into the depression 231A. Similarly, the insulating layer 24, in which the depression 24A serving as the mitigation section is formed, and the insulating layer 237 are adhered to each other, with the adhesion section 26 interposed therebetween (FIG. 10C). In this process, the top of the adhesion section 26 is fitted into the depression 24A. The sensor device 20 is thus manufactured.

[Effects]

Next, effects of the sensor device 20 will be described by comparison with a comparative example.

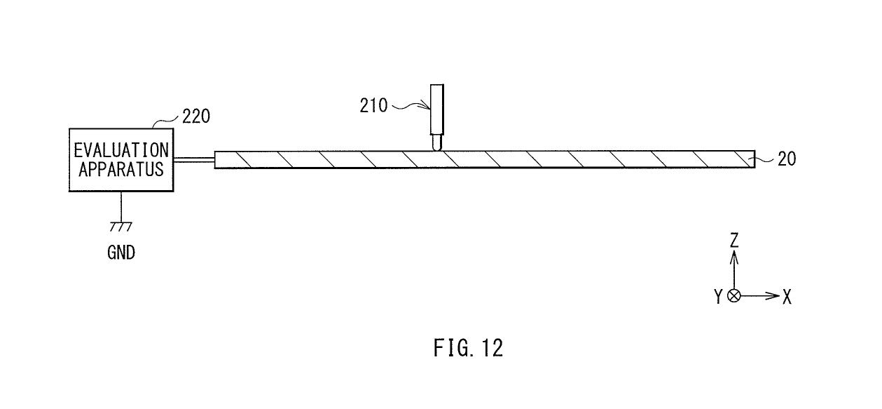

FIGS. 11 and 12 each illustrate an example of an apparatus that evaluates a response speed of the sensor device 20. FIG. 11 illustrates an example of using a laser displacement gauge 200 that measures a displacement of a surface of the sensor device 20. FIG. 12 illustrates an example of using an evaluation apparatus 220 that measures a displacement of the surface of the sensor device 20.

The laser displacement gauge 200 measures a displacement of the surface of the sensor device 20, by irradiating the surface of the sensor device 20 with a laser beam L, and measuring a phase change of a reflected light of the laser beam L. For example, the laser displacement gauge 200 may measure a displacement of the surface of the unloaded sensor device 20 over time, after a state in which the surface of the sensor device 20 is pressed by a jig 210.

The evaluation apparatus 220 may be, for example, connected to the lower electrode 232 and the upper electrode 235 of the sensor device 20 through a flexible printed circuit (FPC). For example, the evaluation apparatus 220 may apply a voltage to the sensor device 20, and may measure a displacement of the surface of the sensor device 20 by utilizing a change in an output from the sensor device 20. For example, the evaluation apparatus 220 may measure a displacement of the surface of the unloaded sensor device 20 over time, after a state in which the surface of the sensor device 20 is pressed by the jig 210.

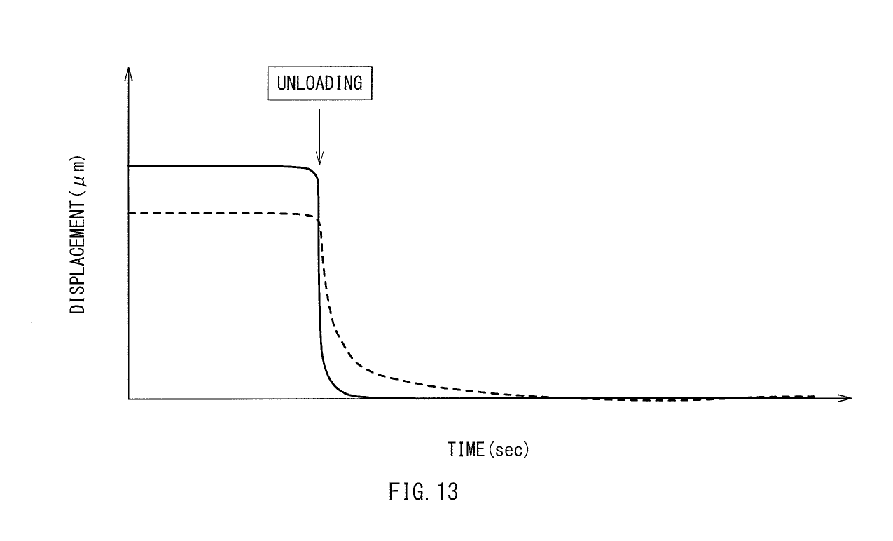

FIG. 13 illustrates an example of a response characteristic of the sensor device 20, together with a response characteristic of a sensor device according to the comparative example. In FIG. 13, a horizontal axis represents the time, and a vertical axis represents the displacement of the surface of the sensor device 20. A surface position of the sensor device 20 when the jig 210 is not in contact with the surface of the sensor device 20 is an origin point of the vertical axis. A solid line in FIG. 13 is a result of a change with time in a displacement of the surface of the sensor device 20. A dashed line in FIG. 13 is a result of a change with time in a surface displacement of the sensor device according to the comparative example.

As illustrated in FIG. 13, the surface position of the sensor device 20 quickly returns to the original position at the time of unloading, as compared with the surface position of the sensor device according to the comparative example. In other words, the response speed of the sensor device 20 is considerably higher than a response speed of the sensor device according to the comparative example. One reason for this will be described below, together with a configuration of the sensor device according to the comparative example.

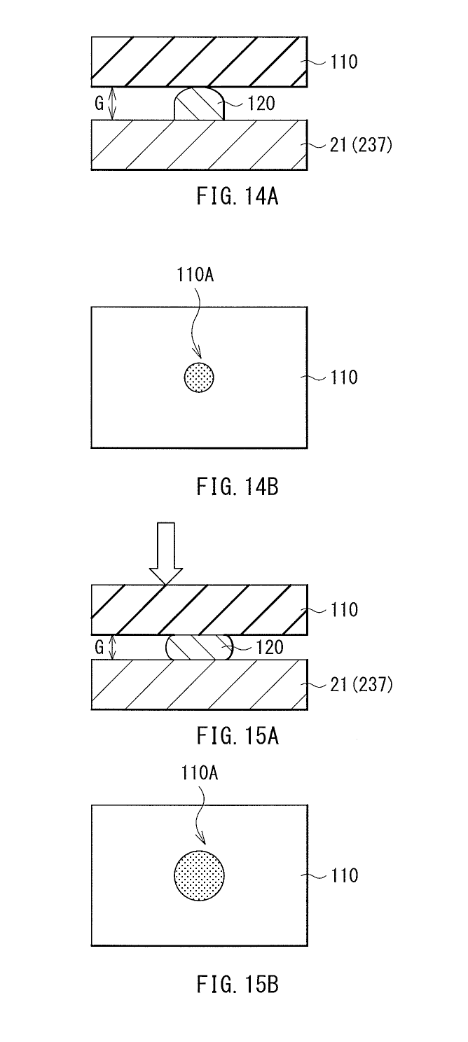

FIG. 14A is an enlarged view illustrating an example of a cross-sectional configuration of an adhesion section 120 and a neighborhood thereof in the sensor device according to the comparative example. FIG. 14B illustrates an example of an area of a contact part 110A between an insulating layer 110 and the adhesion section 120 in the sensor device according to the comparative example. FIG. 15A illustrates an example of a shape change of the adhesion section 120 when the insulating layer 110 is pressed. FIG. 15B illustrates an example of the area of the contact part 110A between the insulating layer 110 and the adhesion section 120 when the insulating layer 110 is pressed. It is to be noted that the sensor device according to the comparative example is equivalent to the sensor device 20 when the adhesion section 120 is provided in place of the adhesion section 25 or 26, and the insulating layer 110 is provided in place of the insulating layer 231 or 24, in the sensor device 20.

Each of the adhesion sections 120 is formed of an adhesive material having elasticity, as with the adhesion sections 25 and 26. Each of the adhesion sections 120 is in contact with the conductive layer 21 (or the insulating layer 237) and the insulating layer 110. Of each of the adhesion sections 120, a top on the insulating layer 110 side is round, and may be shaped like, for example, a part of a sphere. The insulating layer 110 is shaped like a sheet, and has a position facing each of the adhesion sections 120 is a flat surface. The area of the contact part 110A between the insulating layer 110 and the adhesion section 120 is considerably small, as compared with the areas of the contact parts 231B and 24B.

When the insulating layer 110 is pressed, the adhesion section 120 is squashed by receiving pressure from the insulating layer 110 in a thickness direction. A gap G between the insulating layer 110 and the conductive layer 21 (or the insulating layer 237) is narrower than the gap G before the pressing. The round top of the adhesion section 120 is squashed and flattened. Therefore, the area of the contact part 110A greatly changes, as compared with the area before the pressing. Subsequently, upon being unloaded, the flattened adhesion section 120 returns to the original shape by restoring force thereof. At this moment, the restoring force of the adhesion section 120 is resisted by adhesive strength on the top of the adhesion section 120. In general, an adhesive material has low elasticity, and a restoration speed of the adhesive material is greatly influenced by adhesive strength thereof. Therefore, the restoration speed of the flattened adhesion section 120 is lowered by resistance of the adhesive strength on the top of the adhesion section 120. For this reason, it takes a considerably long time for the adhesion section 120 to return to the original shape.

In contrast, in the sensor device 20, the area of the contact part 231B between the adhesion section 25 and the insulating layer 231, and the area of the contact part 24B between the adhesion section 26 and the insulating layer 24 hardly differ from those before the pressing. In the sensor device 20, as compared with a case in which the depressions 231A and 24A each serving as the mitigation section are not provided, an increase in adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not resisted by the adhesive strength on the tops of the adhesion sections 25 and 26, respectively. Hence, the adhesion sections 25 and 26 each return to the original shape in a considerably short time. Accordingly, as compared with the comparative example, it is possible to reduce time from unloading to returning of each of the adhesion sections 25 and 26 to the original shape. Accordingly, it is possible to reduce a decline in the response speed.

In addition, in the sensor device 20, of the adhesion sections 25 and 26, the tops on the insulating layers 231 and 24 sides are fitted into the depressions 231A and 24A, respectively, and are in contact with the inner surfaces of the depressions 231A and 24A, respectively. This makes it possible to increase the area of the contact part 231B between the insulating layer 231 and the adhesion section 25, as compared with the comparative example. As a result, as compared with the comparative example, it is possible to reduce a possibility of peeling of the adhesion sections 25 and 26 off the insulating layers 231 and 24, respectively.

### 2. Modifications of First Embodiment

Next, modifications of the sensor device 20 of the above-described embodiment will be described.

[Modification 1]

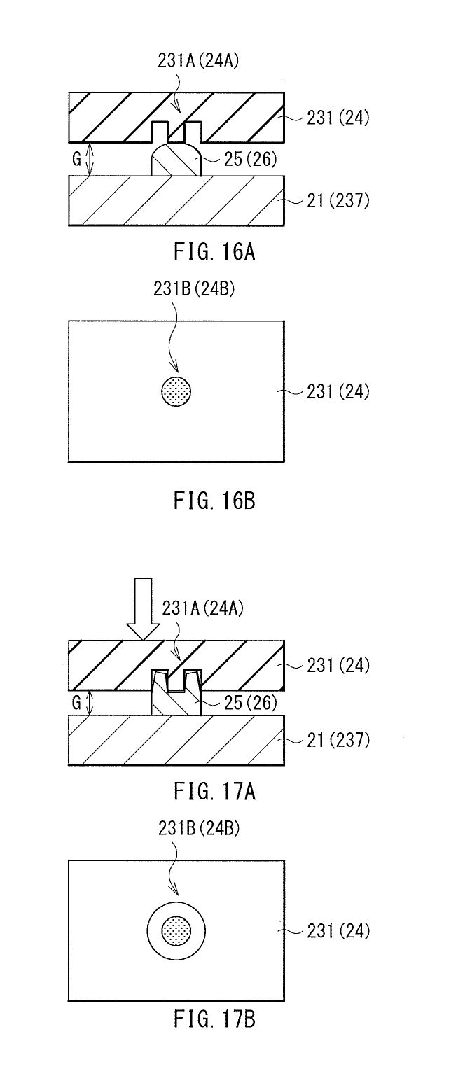

FIG. 16A is an enlarged view of a modification of the cross-sectional configuration of each of the adhesion sections 25 and 26 as well as a neighborhood thereof in the sensor device 20 of the above-described embodiment. FIG. 16B illustrates an example of each of the area of the contact part 231B between the insulating layer 231 and the adhesion section 25, and the area of the contact part 24B between the insulating layer 24 and the adhesion section 25, in FIG. 16A.

In the present modification, each of the adhesion sections 25 is in contact with the conductive layer 21 and the insulating layer 231. Of each of the adhesion sections 25, the top on the insulating layer 231 side is round, and may be shaped like, for example, a part of a sphere. The insulating layer 231 has the depression 231A as the mitigation section, at a position facing each of the adhesion sections 25. The depression 231A may be formed, for example, by transferring the shape of a mold to a resin film. The depression 231A is annular. In the insulating layer 231, a central part of the depression 231A has a projection that is surrounded by the inner surface of the depression 231A. For example, each of the adhesion sections 25 may be in contact with the projection formed in the central part of the depression 231A. In this case, the area of the contact part 231B between the insulating layer 231 and the adhesion section 25 is substantially equal to an area of a top surface of the projection formed in the central part of the depression 231A.

In the present modification, each of the adhesion sections 26 is in contact with the insulating layers 237 and 24. Of each of the adhesion sections 26, the top on the insulating layer 24 side is round, and may be shaped like, for example, a part of a sphere. The insulating layer 24 has the depression 24A as the mitigation section, at a position facing each of the adhesion sections 26. The depression 24A may be formed, for example, by transferring the shape of a mold to a resin film. The depression 24A is annular. In the insulating layer 24, a central part of the depression 24A has a projection that is surrounded by the inner surface of the depression 24A. For example, each of the adhesion sections 26 may be in contact with the projection formed in the central part of the depression 24A. In this case, the area of the contact part 24B between he insulating layer 24 and the adhesion section 26 is substantially equal to an area of a top surface of the projection formed in the central part of the depression 24A.

FIG. 17A illustrates an example of each of a shape change of the adhesion section 25 when the insulating layer 231 is pressed, and a shape change of the adhesion section 26 when the insulating layer 24 is pressed. FIG. 17B illustrates an example of each of the area of the contact part 231B between the insulating layer 231 and the adhesion section 25 when the insulating layer 231 is pressed, and the area of the contact part 24B between the insulating layer 24 and the adhesion section 26 when the insulating layer 24 is pressed.

When the insulating layer 231 is pressed, the adhesion section 25 is squashed by receiving pressure from the insulating layer 231 in a thickness direction. The gap G between the insulating layer 231 and the conductive layer 21 becomes narrower than the gap G before the pressing. At this moment, a part of the adhesion section 25 enters the depression 231A, and the depression 231A suppresses an increase in the area of the contact part 231B between the adhesion section 25 and the insulating layer 231. When an outer diameter of the depression 231A is equal to a diameter of the adhesion section 25, for example, as illustrated in FIGS. 17A and 17B, an outer edge of the depression 231A and the adhesion section 25 may be in contact with each other. Therefore, the outer diameter of the depression 231A may be preferably larger than the diameter of the adhesion section 25.

When the insulating layer 24 is pressed, the adhesion section 26 is squashed by receiving pressure from the insulating layer 24 in a thickness direction. The gap G between the insulating layers 24 and 237 becomes narrower than the gap G before the pressing. At this moment, a part of the adhesion section 26 enters the depression 24A, and the depression 24A suppresses an increase in the area of the contact part 24B between the adhesion section 26 and the insulating layer 24. When an outer diameter of the depression 24A is equal to a diameter of the adhesion section 26, for example, as illustrated in FIGS. 17A and 17B, an outer edge of the depression 24A and the adhesion section 26 may be in contact with each other. Therefore, the outer diameter of the depression 24A may be preferably larger than the diameter of the adhesion section 26.

In the present modification, in the sensor device 20, the area of the contact part 231B between the adhesion section 25 and the insulating layer 231, and the area of the contact part 24B between the adhesion section 26 and the insulating layer 24 each hardly differ from the area before the pressing. As compared with a case in which the depressions 231A and 24A each serving as the mitigation section are not provided, an increase in the adhesion strength when the gap G is reduced is suppressed. The adhesion strength is built between the adhesion section 25 and the insulating layer 231 and between the adhesion section 26 and the insulating layer 24. Therefore, the restoration speeds of the flattened adhesion sections 25 and 26 are not resisted by the adhesive strength on the tops of the adhesion sections 25 and 26, respectively. Hence, the adhesion sections 25 and 26 each return to the original shape in a considerably short time. Therefore, as compared with the above-described comparative example, it is possible to reduce the time from unloading to returning of each of the adhesion sections 25 and 26 to the original shape. Accordingly, it is possible to reduce a decline in the response speed.

[Modification 2]

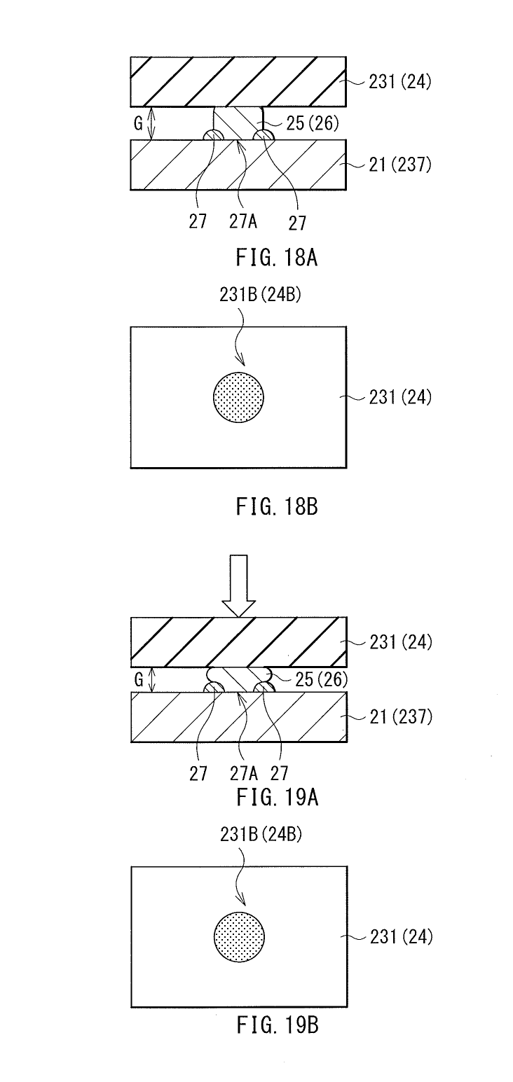

FIG. 18A is an enlarged view of a modification of the cross-sectional configuration of each of the adhesion sections 25 and 26 as well as a neighborhood thereof in the sensor device 20 of the above-described embodiment. FIG. 18B illustrates an example of the area of each of the contact part 231B between the insulating layer 231 and the adhesion section 25, and the contact part 24B between the insulating layer 24 and the adhesion section 26, in FIG. 18A.

In the present modification, the sensor device 20 has a plurality of convex annular bodies 27 as an mitigation section, on the surface of each of the conductive layer 21 and the insulating layer 237. The annular body 27 is provided for each of the adhesion sections 25 and each of the adhesion sections 26. Each of the adhesion sections 25 is in contact with the conductive layer 21 and the insulating layer 231. Each of the adhesion sections 26 is in contact with the insulating layers 237 and 24. Each of the adhesion sections 25 is in contact with the surface of the conductive layer 21, through an opening 27A of the annular body 27, as well as the annular body 27. Each of the adhesion sections 26 is in contact with the surface of the insulating layer 237, through the opening 27A of the annular body 27, as well as the annular body 27.

Of the adhesion sections 25 and 26, the round tops on the insulating layers 231 and 24 sides are suppressed to be flattened by the annular body 27, in a process of manufacturing the sensor device 20. Therefore, of the adhesion sections 25 and 26, the tops on the insulating layers 231 and 24 sides are flat or substantially flat. Each of the annular bodies 27 is formed by printing on the surface of the conductive layer 21 and the insulating layer 237. The annular body 27 has a height less than a height of each of the adhesion sections 25 and 26. For example, the area of the contact part 231B between the insulating layer 231 and the adhesion section 25, and the area of the contact part 24B between the insulating layer 24 and the adhesion section 26 may be substantially equal to cross-sectional areas of the adhesion sections 25 and 26, respectively.

FIG. 19A illustrates an example of each of a shape change of the adhesion section 25 when the insulating layer 231 is pressed, and a shape change of the adhesion section 26 when the insulating layer 24 is pressed. FIG. 19B illustrates an example of each of the area of the contact part 231B between the insulating layer 231 and the adhesion section 25 when the insulating layer 231 is pressed, and the area of the contact part 24B between the insulating layer 24 and the adhesion section 26 when the insulating layer 24 is pressed.

When the insulating layers 231 and 24 are pressed, and the adhesion sections 25 and 26 are squashed by receiving pressure from the insulating layers 231 and 24, respectively, in a thickness direction. The gap G between the insulating layer 231 and the conductive layer 21 or between the insulating layers 24 and 237 becomes narrower than the gap G before the pressing. Of the adhesion sections 25 and 26, the tops on the insulating layers 231 and 24 sides, respectively, are flat or substantially flat and therefore do not have or hardly have roundness, even before the pressing. Therefore, there is almost no change between the areas of the contact parts 231B and 24B before the pressing and the areas of the contact parts 231B and 24B after the pressing. As compared with a case in which the annular body 27 is not provided, an increase in the adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not resisted by the adhesive strength on the tops of the adhesion sections 25 and 26, respectively. Hence, the adhesion sections 25 and 26 each return to the original shape in a considerably short time. Therefore, as compared with the comparative example, it is possible to reduce the time from unloading to returning of each of the adhesion sections 25 and 26 to the original shape. Accordingly, it is possible to reduce a decline in the response speed.

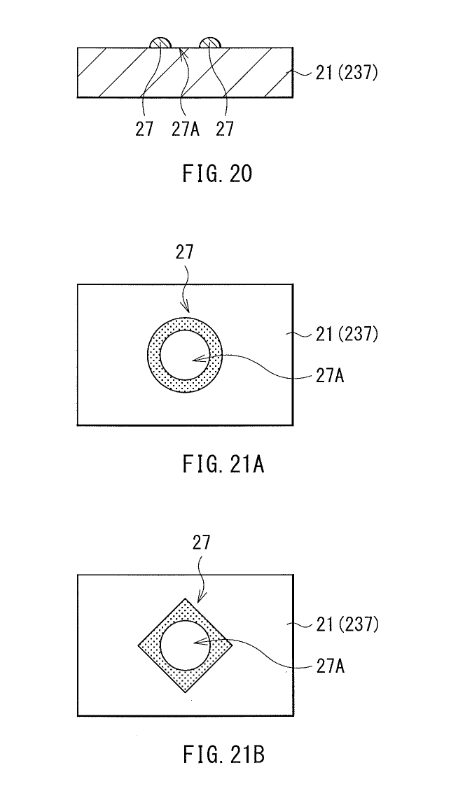

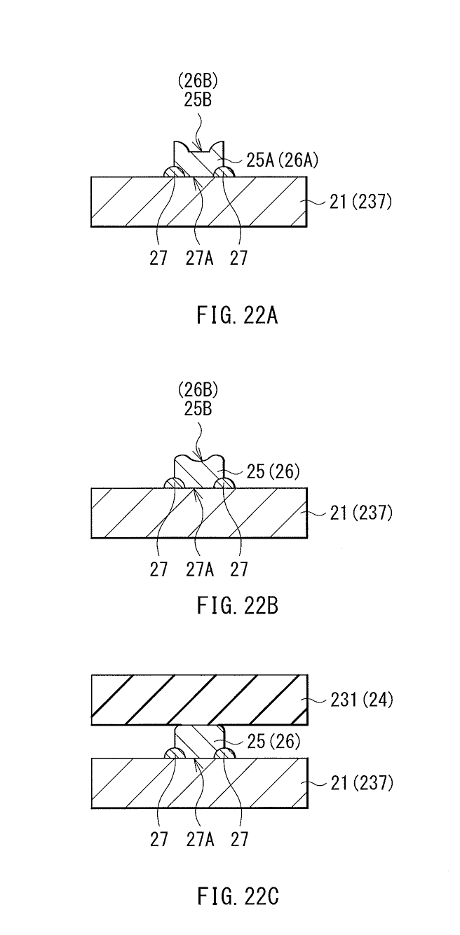

FIG. 20 illustrates an example of a process in a method of manufacturing the sensor device 20. FIGS. 21A and 21B each illustrate an example of a plane configuration of the annular body 27. FIGS. 22A, 22B and 22C illustrate an example of a process following the process in FIG. 20.

First, the plurality of annular bodies 27 two-dimensionally arranged are printed on the surface of each of the conductive layer 21 and the insulating layer 237 (FIG. 20). The annular body 27 may be shaped like, for example, a ring as illustrated in FIG. 21A, or may be shaped like, for example, a rhombic ring as illustrated in FIG. 21B. The annular body 27 is configured of a printable resin-based material. A height of the annular body 27 and a diameter of the opening 27A may be preferably set at values by which depressions 25B and 26B that may be formed on the tops of the adhesion sections 25 and 26 are allowed to become as shallow as possible, when a treatment of increasing viscosity to be described later is performed.

Next, the plurality of adhesion sections 25A two-dimensionally arranged are printed on the surface of the conductive layer 21 (FIG. 22A). Specifically, the plurality of adhesion sections 25A are each printed on a part, which is exposed inside the opening 27A of each of the annular bodies 27, of the conductive layer 21. The plurality of adhesion sections 25A are each printed also on a surface, which is adjacent to this part, of the annular body 27. Similarly, the plurality of adhesion sections 26A two-dimensionally arranged are printed on the surface of the insulating layer 237 (FIG. 22A). Specifically, the plurality of adhesion sections 26A are each printed on a part, which is exposed inside the opening 27A of each of the annular bodies 27, of the insulating layer 237. The plurality of adhesion sections 26A are each printed also on a surface, which is adjacent to this part, of the annular body 27. It is to be noted that, in FIG. 22A, the adhesion sections 25A and 26A are square-cornered, but the tops of the adhesion sections 25A and 26A may be slightly rounded, depending on the way of printing, in some cases.

Next, the treatment of increasing viscosity of each of the adhesion sections 25A and 26A is performed. For example, the viscosity of each of the adhesion sections 25A and 26A may be increased by heating, ultraviolet irradiation, moisture curing, or electron beam irradiation, to form the adhesion sections 25 and 26. In this process, the adhesion sections 25 and 26 become temporarily soft, so that the tops of the adhesion sections 25 and 26 become flat due to surface tension (FIG. 22B). Next, the flat insulating layer 231 without the depression 231A and the conductive layer 21 are adhered to each other, with the adhesion section 25 interposed therebetween (FIG. 22C). Similarly, the flat insulating layer 24 without the depression 24A and the insulating layer 237 are adhered to each other, with the adhesion section 26 interposed therebetween (FIG. 22C). The sensor device 20 is thus manufactured.

In the present modification, the adhesion sections 25A and 26A as well as the annular body 27 are formed by printing. Therefore, it possible to reduce a decline in the response speed by a simple manufacturing method, as compared with the case in which the depressions 231A and 24A are provided in the insulating layers 231 and 24, respectively.

[Modification 3]

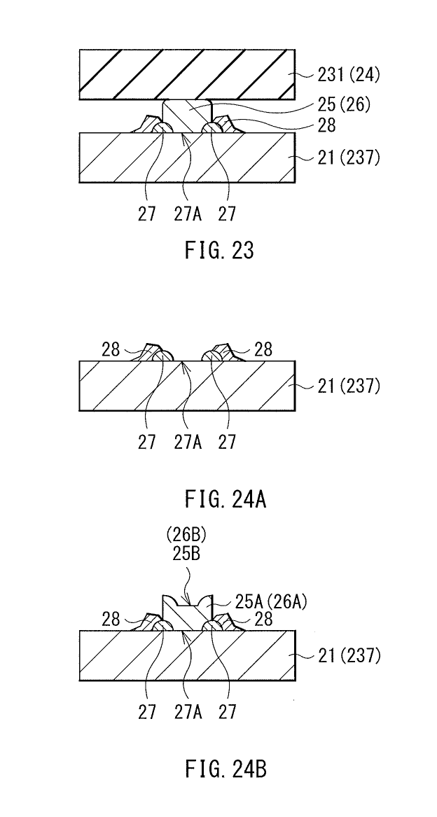

FIG. 23 is an enlarged view of a modification of the cross-sectional configuration of each of the adhesion sections 25 and 26 as well as a neighborhood thereof in the sensor device 20 of the above-described embodiment.

The sensor device 20 of the present modification is equivalent to the sensor device 20 according to Modification 2 further provided with a prevention layer 28. The prevention layer 28 prevents wet spread of the adhesion sections 25A and 26A from reaching a peripheral edge of the annular body 27, in a process of manufacturing the sensor device 20. The prevention layer 28 is provided to be in contact with an outer edge of the annular body 27, and a part, which surrounds the annular body 27, of each of the conductive layer 21 and the insulating layer 231.

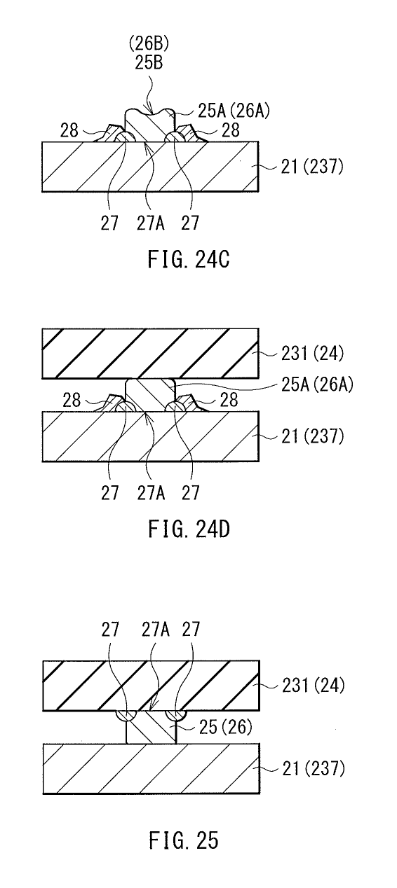

FIG. 24A illustrates an example of a process in a method of manufacturing the sensor device 20. FIG. 24B illustrates an example of a process following the process in FIG. 24A. FIG. 24C illustrates an example of a process following the process in FIG. 24B. FIG. 24D illustrates an example of a process following the process in FIG. 24C.

First, the plurality of annular bodies 27 two-dimensionally arranged are formed by printing on the surface of each of the conductive layer 21 and the insulating layer 237 (FIG. 24A). Next, on the surface of each of the conductive layer 21 and the insulating layer 237, the prevention layer 28 is printed. Specifically, the prevention layer 28 is formed to be in contact with the outer edge of the annular body 27, and the part, which surrounds the annular body 27, of each of the conductive layer 21 and the insulating layer 231.

Next, the plurality of adhesion sections 25A two-dimensionally arranged are formed by printing on the surface of the conductive layer 21 (FIG. 24B). Specifically, the plurality of adhesion sections 25A are each printed on a part, which is exposed inside the opening 27A of each of the annular bodies 27, of the conductive layer 21. The plurality of adhesion sections 25A are each printed also on a surface, which is adjacent to this part, of the annular body 27. Similarly, the plurality of adhesion sections 26A two-dimensionally arranged are printed on the surface of the insulating layer 237 (FIG. 24B). Specifically, the plurality of adhesion sections 26A are each printed on a part, which is exposed inside the opening 27A of each of the annular bodies 27, of the insulating layer 237. The plurality of adhesion sections 26A are each printed also on a surface, which is adjacent to this part, of the annular body 27.

Next, the treatment of increasing viscosity of each of the adhesion sections 25A and 26A is performed. For example, the viscosity of each of the adhesion sections 25A and 26A may be increased by heating, ultraviolet irradiation, moisture curing, or electron beam irradiation, to form the adhesion sections 25 and 26. In this process, the adhesion sections 25 and 26 become temporarily soft, so that the tops of the adhesion sections 25 and 26 become flat due to surface tension (FIG. 24C). In addition, in this process, wet spread of the adhesion sections 25A and 26A is prevented from reaching the peripheral edge of the annular body 27, by the effect of the prevention layer 28. Next, the flat insulating layer 231 without the depression 231A and the conductive layer 21 are adhered to each other, with the adhesion section 25 interposed therebetween (FIG. 24D). Similarly, the flat insulating layer 24 without the depression 24A and the insulating layer 237 are adhered to each other, with the adhesion section 26 interposed therebetween (FIG. 24D). The sensor device 20 is thus manufactured.

In the present modification, the prevention layer 28 is provided to prevent wet spread of the adhesion sections 25A and 26A from reaching the peripheral edge of the annular body 27, in the process of manufacturing the sensor device 20. This makes it possible to control flatness of the top surfaces of the adhesion sections 25 and 26 more easily, in the process of manufacturing the sensor device 20.

[Modification 4]

FIG. 25 is an enlarged view of a modification of the cross-sectional configuration of each of the adhesion sections 25 and 26 as well as a neighborhood thereof in the sensor device 20 of the above-described embodiment.

In the present modification, the sensor device 20 has the plurality of convex annular bodies 27 provided on each of the insulating layers 231 and 24, as the mitigation section. The annular body 27 is provided for each of the adhesion sections 25 and 26. In other words, the sensor device 20 of the present modification is equivalent to the sensor device 20 of Modification 2 provided with the plurality of convex annular bodies 27 on the surface of each of the insulating layers 231 and 24. Each of the adhesion sections 25 is in contact with the conductive layer 21 and the insulating layer 231. Each of the adhesion sections 26 is in contact with the insulating layers 237 and 24. Each of the adhesion sections 25 is in contact with the surface of the insulating layer 231, through the opening 27A of the annular body 27, as well as the annular body 27. Each of the adhesion sections 26 is in contact with the surface of the insulating layer 24, through the opening 27A of the annular body 27, as well as the annular body 27. The annular body 27 fills a gap between the adhesion section 25 having a round top on the insulating layer 231 side and the insulating layer 231, and a gap between the adhesion section 26 having a round top on the insulating layer 24 side and the insulating layer 24, in a process of manufacturing the sensor device 20. For example, the area of a contact part between the insulating layer 231 with the annular body 27 and the adhesion section 25, and the area of a contact part between the insulating layer 24 with the annular body 27 and the adhesion section 26 may be substantially equivalent to a cross-sectional area of the adhesion section 25 and a cross-sectional area of the adhesion section 26, respectively.

In the sensor device 20 of the present modification, the area of the contact part between the insulating layer 231 with the annular body 27 and the adhesion section 25, and the area of the contact part between the insulating layer 24 with the annular body 27 and the adhesion section 26 hardly differ from those areas before the pressing. Between the adhesion section 25 and the insulating layer 231 with the annular body 27, and between the adhesion section 26 and the insulating layer 24 with the annular body 27, an increase in the adhesion strength when the gap G is reduced is suppressed, as compared with a case in which the annular body 27 serving as the mitigation section is not provided. Therefore, the restoration speeds of the flattened adhesion sections 25 and 26 are not resisted by the adhesive strength on the tops of the adhesion sections 25 and 26. Hence, the adhesion sections 25 and 26 each return to the original shape in a considerably short time. Therefore, as compared with the above-described comparative example, it is possible to reduce the time from unloading to returning of each of the adhesion sections 25 and 26 to the original shape. Accordingly, it is possible to reduce a decline in the response speed.

[Modification 5]

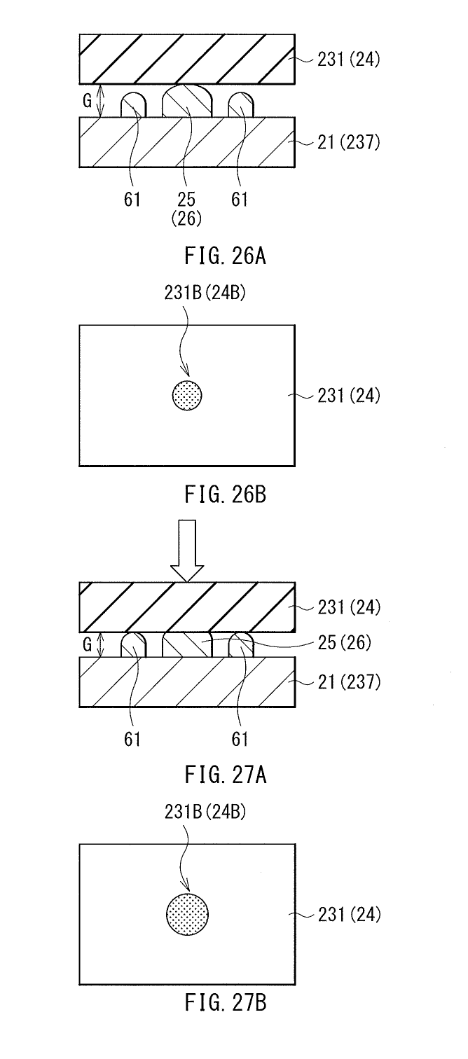

FIG. 26A is an enlarged view of a modification of the cross-sectional configuration of each of the adhesion sections 25 and 26 as well as a neighborhood thereof in the sensor device 20 of the above-described embodiment. FIG. 26B illustrates an example of the area of each of the contact part 231B between the insulating layer 231 and the adhesion section 25, and the contact part 24B between the insulating layer 24 and the adhesion section 26, in FIG. 26A.

In the present modification, the sensor device 20 has a plurality of projections 61 as the mitigation section. The plurality of projections 61 are each provided at a position on the surface of each of the conductive layer 21 and the insulating layer 237, without being in contact with each of the adhesion sections 25 and 26. Each of the adhesion sections 25 is in contact with the conductive layer 21 and the insulating layer 231. Each of the adhesion sections 26 is in contact with the insulating layers 237 and 24. For example, each of the adhesion sections 25 and each of the adhesion sections 26 may have a round top on the insulating layer 231 side and a round top on the insulating layer 24 side, respectively. Each of the adhesion sections 25 and 26 are not in contact with each of the projections 61, and there is a clearance between each of the projections 61 and each of the adhesion sections 25 and 26. Each of the projections 61 controls the gap G. For example, each or each plurality of the projections 61 may be allocated to each of the adhesion sections 25 and 26. When external force, which reduces the gap G between the conductive layer 21 and the insulating layer 231 and between the insulating layers 237 and 24, is applied to none of the insulating layers 24, 231, 237 and the conductive layer 21, each of the projections 61 is in contact with only each of the conductive layer 21 and the insulating layer 237. In other words, when a pressing force is not applied to the sensor device 20, there is a clearance between the top of each of the projections 61 and each of the insulating layers 231 and 24. Each of the projections 61 has non-adhesiveness. Therefore, when being brought into contact with the insulating layer 231, each of the projections 61 does not adhere thereto, and similarly, when being brought into contact with the insulating layer 24, each of the projections 61 does not adhere thereto. Each of the projections 61 is formed on the surface of the conductive layer 21 or the insulating layer 237 by printing.

FIG. 27A illustrates an example of a shape change of the adhesion section 25 when the insulating layer 231 is pressed or a shape change of the adhesion section 26 when the insulating layer 24 is pressed. FIG. 27B illustrates an example of the area of the contact part 231B between the insulating layer 231 and the adhesion section 25 when the insulating layer 231 is pressed, or the area of the contact part 24B between the insulating layer 24 and the adhesion section 26 when the insulating layer 24 is pressed.

When the insulating layers 231 and 24 are pressed, the adhesion sections 25 and 26 are squashed by receiving pressure in a thickness direction, from the insulating layers 231 and 24, respectively. The gap G between the insulating layer 231 and the conductive layer 21 or between the insulating layers 24 and 237 becomes narrower than the gap G before the pressing. The gap G is controlled by each of the projections 61, not to become narrower than a height of each of the projections 61. Amounts of depression in the adhesion sections 25 and 26 by the insulating layers 231 and 24, respectively, are each limited by each of the projections 61. Therefore, as compared with a case in which a limit by each of the projections 61 is not provided, a difference between the area of the contact part 231B after the pressing and that before the pressing and a difference between the area of the contact part 24B after the pressing and that before the pressing are small. An increase in the adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not much resisted by the adhesive strength on the tops of the adhesion sections 25 and 26, respectively. Hence, the adhesion sections 25 and 26 each return to the original shape in a relatively short time. Therefore, as compared with the above-described comparative example, it is possible to reduce the time from unloading to returning of each of the adhesion sections 25 and 26 to the original shape. Accordingly, it is possible to reduce a decline in the response speed.

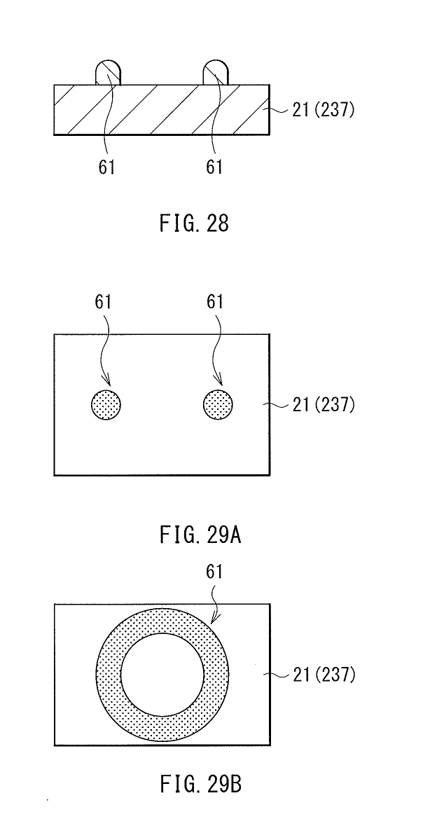

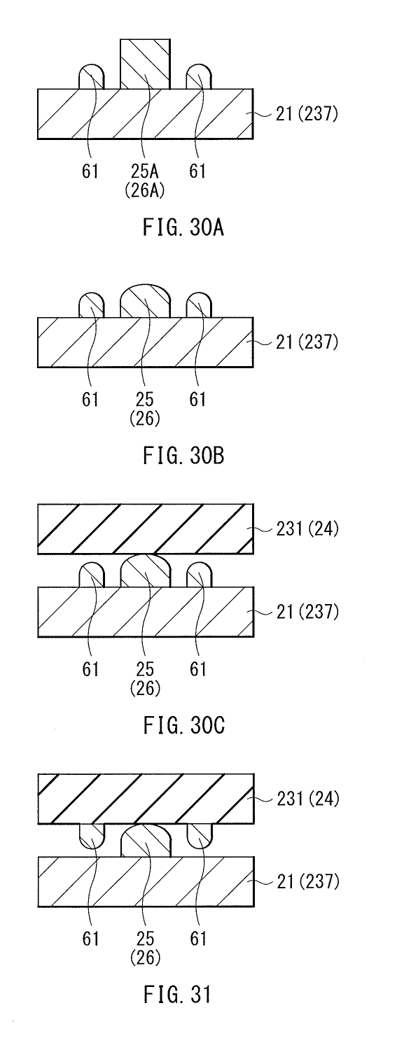

FIG. 28 illustrates an example of a process in a method of manufacturing the sensor device 20. FIGS. 29A and 29B each illustrate an example of a plane configuration of the projection 61. FIG. 30A illustrates an example of a process following the process in FIG. 28, FIG. 30B illustrates an example of a process following the process in FIG. 30A, and FIG. 30C illustrates an example of a process following the process in FIG. 30B.

First, the plurality of projections 61 two-dimensionally arranged are printed on the surface of each of the conductive layer 21 and the insulating layer 237 (FIG. 28). The projections 61 may each be, for example, shaped like a dot as illustrated in FIG. 29A, or may each be, for example, annular as illustrated in FIG. 29B. The projection 61 may be configured of a printable resin-based material. The projection 61 may be preferably disposed at a position not to be in contact with each of the adhesion sections 25 and 26 even when the sensor device 20 is pressed.

Next, the plurality of adhesion sections 25A two-dimensionally arranged are printed on the surface of the conductive layer 21 (FIG. 30A). Specifically, the plurality of adhesion sections 25A are each printed on a surface, which is adjacent to each of the projections 61, of the conductive layer 21, or on a part, which is exposed inside an opening of each of the projections 61, of the conductive layer 21. Similarly, the plurality of adhesion sections 26A two-dimensionally arranged are printed on the surface of the insulating layer 237 (FIG. 30A). Specifically, the plurality of adhesion sections 26A are each printed on a surface, which is adjacent to each of the projections 61, of the insulating layer 237, or on a part, which is exposed inside the opening of each of the projections 61, of the insulating layer 237. It is to be noted that, in FIG. 30A, the adhesion sections 25A and 26A are square-cornered, but the tops of the adhesion sections 25A and 26A may be slightly rounded, depending on the way of printing, in some cases.

Next, the treatment of increasing viscosity of each of the adhesion sections 25A and 26A is performed. For example, the viscosity of each of the adhesion sections 25A and 26A may be increased by heating, ultraviolet irradiation, moisture curing, or electron beam irradiation, to form the adhesion sections 25 and 26. In this process, the adhesion sections 25 and 26 become temporarily soft, so that the tops of the adhesion sections 25 and 26 become flat due to surface tension (FIG. 30B). Next, the flat insulating layer 231 without the depression 231A and the conductive layer 21 are adhered to each other, with the adhesion section 25 interposed therebetween (FIG. 30C). Similarly, the flat insulating layer 24 without the depression 24A and the insulating layer 237 are adhered to each other, with the adhesion section 26 interposed therebetween (FIG. 30C). The sensor device 20 is thus manufactured.

In the sensor device 20 of the present modification, the area of the contact part between the adhesion section 25 and the insulating layer 231, and the area of the contact part between the adhesion section 26 and the insulating layer 24 hardly differ from those areas before the pressing. As compared with a case in which the projections 61 serving as the mitigation section are not provided, an increase in adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not much resisted by the adhesive strength on the tops of the adhesion sections 25 and 26, respectively. Hence, the adhesion sections 25 and 26 each return to the original shape in a relatively short time. Therefore, as compared with the above-described comparative example, it is possible to reduce the time from unloading to returning of each of the adhesion sections 25 and 26 to the original shape. Accordingly, it is possible to reduce a decline in the response speed.

[Modification 6]

FIG. 31 is an enlarged view of a modification of the cross-sectional configuration of each of the adhesion sections 25 and 26 as well as a neighborhood thereof in the sensor device 20 of the above-described embodiment.

In the present modification, the sensor device 20 has the plurality of projections 61 as the mitigation section. The plurality of projections 61 are provided on the surface of each of the insulating layers 231 and 24, and are each provided for each of the adhesion sections 25 and 26. In other words, the sensor device 20 of the present modification is equivalent to the sensor device 20 of the modification 5 in which the plurality of projections 61 are each provided at a position on the surface of each of the insulating layers 231 and 24, without being in contact with each of the adhesion sections 25 and 26. Each of the projections 61 is formed by printing on the surface of each of the insulating layers 231 and 24. For example, each or each plurality of the projections 61 may be allocated to each of the adhesion sections 25 and 26. When external force, which reduces the gap G between the conductive layer 21 and the insulating layer 231 and the gap G between the insulating layers 237 and 24, is applied to none of the insulating layers 24, 231, 237 and the conductive layer 21, each of the projections 61 is in contact with only each of the insulating layers 231 and 24. In other words, when a pressing force is not applied to the sensor device 20, there is a clearance between the top of each of the projections 61 and the conductive layer 21 or the insulating layer 231. Each of the projections 61 has non-adhesiveness. Therefore, when being brought into contact with the conductive layer 21, each of the projections 61 does not adhere thereto, and similarly, when being brought into contact with the insulating layer 237, each of the projections 61 does not adhere thereto.

In the sensor device 20 of the present modification, the area of the contact part between the adhesion section 25 and the insulating layer 231, and the area of the contact part between the adhesion section 26 and the insulating layer 24 hardly differ from those areas before the pressing. As compared with a case in which the projections 61 serving as the mitigation section are not provided, an increase in adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not much resisted by the adhesive strength on the tops of the adhesion sections 25 and 26. Hence, the adhesion sections 25 and 26 each return to the original shape in a relatively short time. Therefore, as compared with the above-described comparative example, it is possible to reduce the time from unloading to returning of each of the adhesion sections 25 and 26 to the original shape. Accordingly, it is possible to reduce a decline in the response speed.

[Modification 7]

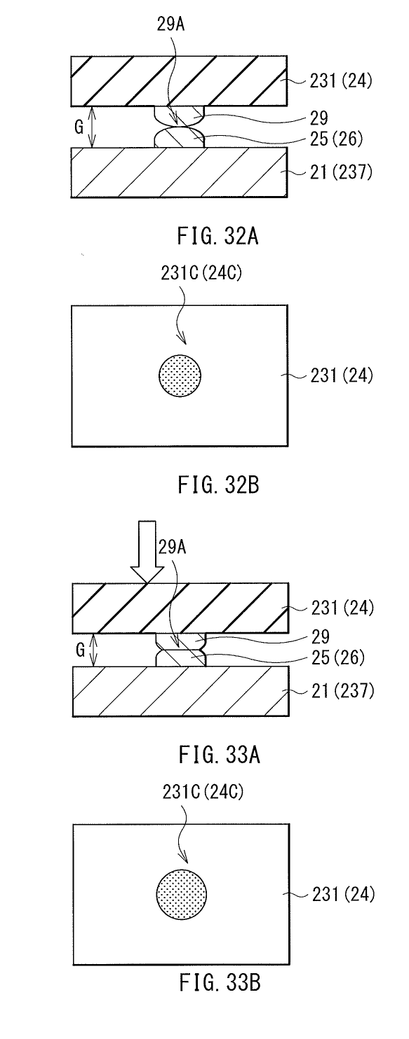

FIG. 32A is an enlarged view of a modification of the cross-sectional configuration of each of the adhesion sections 25 and 26 as well as a neighborhood thereof in the sensor device 20 of the above-described embodiment. FIG. 32B illustrates an example of the area of each of a contact part 231C between the insulating layer 231 and an adhesion section 29 to be described later, and a contact part 24C between the insulating layer 24 and the adhesion section 29, in FIG. 32A.

In the present modification, the sensor device 20 has a plurality of adhesion sections 29 having elasticity as the mitigation section. The adhesion sections 29 are provided on the surface of each of the insulating layers 231 and 24. The adhesion section 29 is equivalent to a specific but not limitative example of “second adhesion section” according to one embodiment of the present application. Each of the adhesion sections 29 is disposed between the insulating layer 231 and the adhesion section 25, and is in contact with the insulating layer 231 and the top of the adhesion section 25. Similarly, each of the adhesion sections 29 is disposed between the insulating layer 24 and the adhesion section 26, and is in contact with the insulating layer 24 and the top of the adhesion section 26. Each of the adhesion sections 29 is formed by printing on the surface of each of the insulating layers 231 and 24. Each of the adhesion sections 25 is formed by printing on the surface of the conductive layer 21. Each of the adhesion sections 26 is formed by printing on the surface of the insulating layer 237.

Each of the adhesion sections 29 is formed of an adhesive material having elasticity. Each of the adhesion sections 29 has a round top on the adhesion section 25 side and the adhesion section 26 side, and may be shaped like, for example, a part of a sphere. The adhesion sections 25, 26, and 29 each have the round top and therefore, an area of a contact part 29A between the adhesion section 29 and each of the adhesion sections 25 and 26 is slightly smaller than each of the contact parts 231C and 24C, respectively. Each of the adhesion sections 29 may be formed, for example, by printing a heat-sensitive adhesive material. The heat-sensitive adhesive material is then heated (or warmed), irradiated with ultraviolet rays, or cured by moisture, so that adhesiveness of the heat-sensitive adhesive material develops. Further, each of the adhesion sections 29 may be formed, for example, by printing an electron-beam sensitive adhesive material. The electron-beam sensitive adhesive material is then irradiated with an electron beam, so that adhesiveness of the electron-beam sensitive adhesive material develops.

FIG. 33A illustrates an example of a shape change of each of the adhesion sections 25, 26, and 29 when the insulating layers 231 and 24 are pressed. FIG. 33B illustrates an example of each of the area of the contact part 231C between the insulating layer 231 and the adhesion section 29, and the area of the contact part 24C between the insulating layer 24 and the adhesion section 29.

When the insulating layers 231 and 24 are pressed, the adhesion sections 25, 26, and 29 are squashed by receiving pressure from the insulating layers 231 and 24, respectively, in a thickness direction. The gap G between the insulating layer 231 and the conductive layer 21 and the gap G between the insulating layers 24 and 237 become narrower than those gaps G before the pressing. Of the adhesion sections 25 and 26, the tops on the insulating layers 231 and 24 sides, respectively, are flat or substantially flat and therefore do not have or hardly have roundness. Hence, the area of the contact part 29A after the pressing is slightly larger than the area of the contact part 29A before the pressing. On the other hand, there is almost no change between the areas of the contact parts 231C and 24C before the pressing and those after the pressing.

Here, a change in the area of the contact part 29A does not much influence the restoration speeds of the adhesion sections 25 and 26. In addition, the restoration speeds of the flattened adhesion sections 25, 26, and 29 are not resisted by the adhesive strength at bottoms of the adhesion sections 25, 26, and 29. Hence, the adhesion sections 25, 26, and 29 each return to the original shape in a considerably short time. Therefore, as compared with the above-described comparative example, it is possible to reduce the time from unloading to returning of each of the adhesion sections 25, 26, and 29 to the original shape. Accordingly, it is possible to reduce a decline in the response speed.

[Modification 8]

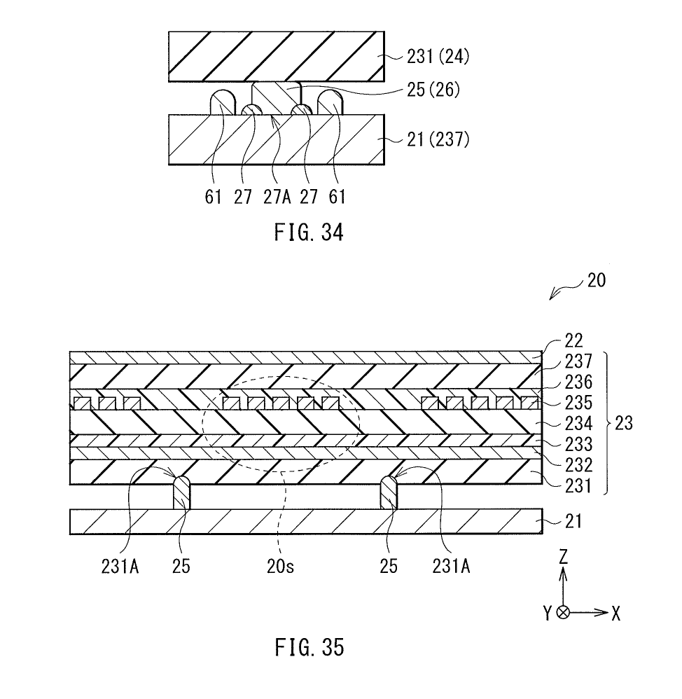

FIG. 34 is an enlarged view of a modification of the cross-sectional configuration of each of the adhesion sections 25 and 26 as well as a neighborhood thereof in the sensor device 20 of the above-described embodiment.

In the present modification, the sensor device 20 has the plurality of annular bodies 27 and the plurality of projections 61 as the mitigation section, on the surface of each of the conductive layer 21 and the insulating layer 237. In other words, the sensor device 20 of the present modification is equivalent to the sensor device 20 of Modification 2 provided with the plurality of projections 61 at positions on the surface of each of the conductive layer 21 and the insulating layer 237, without being in contact with each of the adhesion sections 25 and 26.

In the sensor device 20 of the present modification, the areas of the contact parts 231B and 24B after the pressing hardly differ from the areas of the contact parts 231B and 24B before the pressing. In addition, as compared with a case in which the annular bodies 27 and the projections 61 are not provided, an increase in adhesion strength between the adhesion section 25 and the insulating layer 231 and between the adhesion section 26 and the insulating layer 24 when the gap G is reduced is suppressed. Therefore, the restoration speeds of the flattened adhesion sections 25 and 26 are not resisted by the adhesive strength on the tops of the adhesion sections 25 and 26, respectively. Hence, the adhesion sections 25 and 26 each return to the original shape in a considerably short time. Therefore, as compared with the above-described comparative example, it is possible to reduce the time from unloading to returning of each of the adhesion sections 25 and 26 to the original shape. Accordingly, it is possible to reduce a decline in the response speed.

[Modification 9]

FIG. 35 illustrates a modification of the cross-sectional configuration of the sensor device 20 according to each of the above-described embodiment and modifications (Modifications 1 to 8). The sensor device 20 of the present modification is equivalent to the sensor device 20 according to each of the above-described embodiment and modifications (Modifications 1 to 8) from which the adhesive section 26 and the insulating layer 24 formed near the display panel 10 are removed. In this case, it is possible to reduce the thickness of the sensor device 20, as compared with the sensor device 20 according to each of the above-described embodiment and modifications (Modifications 1 to 8).

[Modification 10]

In each of the above-described embodiment and modifications (Modifications 1 to 8), the mitigation section is provided for both of the adhesive sections 25 and 26. However, the mitigation section may be provided for only one of the adhesive section 25 and the adhesive section 26.

### 3. Second Embodiment

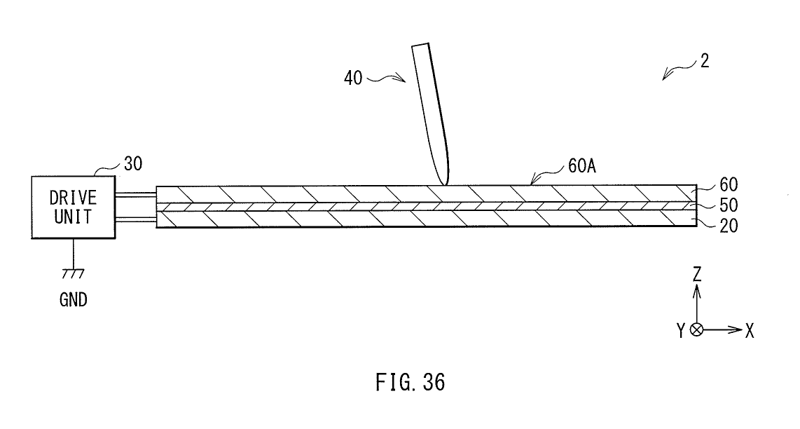

FIG. 36 illustrates an example of a cross-sectional configuration of an input apparatus 2 according to a second embodiment of the present application. The input apparatus 2 is equivalent to the display apparatus 1 including the sensor device 20 according to each of the above-described embodiment and modifications (Modifications 1 to 10) provided with a substrate 60 in place of the display panel 10.

The substrate 60 has an operation surface 60A. The substrate 60 may be, for example, an opaque resin plate having flexibility or an opaque metal plate having flexibility. The sensor device 20 detects a contact position or a pressed position of an object such as the pen 40 on the operation surface 60A, and outputs a detection result (a detection signal) to the drive unit 30.

By applying a voltage to the sensor device 20, the drive unit 30 drives the sensor device 20, and receives the detection signal from the sensor device 20. Further, the drive unit 30 generates an image signal based on the received detection signal, and outputs the generated image signal to outside. The pen 40 is caused to touch or press the operation surface 60A. The sensor device 20 detects a contact position or a pressed position of the pen 40, on the operation surface 60A. It is to be noted that the pen 40 may be omitted. In this case, a finger may be used in place of the pen 40.

Next, effects of the input apparatus 2 of the present embodiment will be described. In the present embodiment, the mitigation section is provided for the sensor device 20 in a manner similar to the above-described embodiment. Therefore, as compared with the above-described comparative example, it is possible to reduce the time from unloading to returning of each of the adhesion sections 25 and 26 (or the adhesion sections 25, 26, and 29) to the original shape. Accordingly, it is possible to reduce a decline in the response speed.

### 4. Third Embodiment

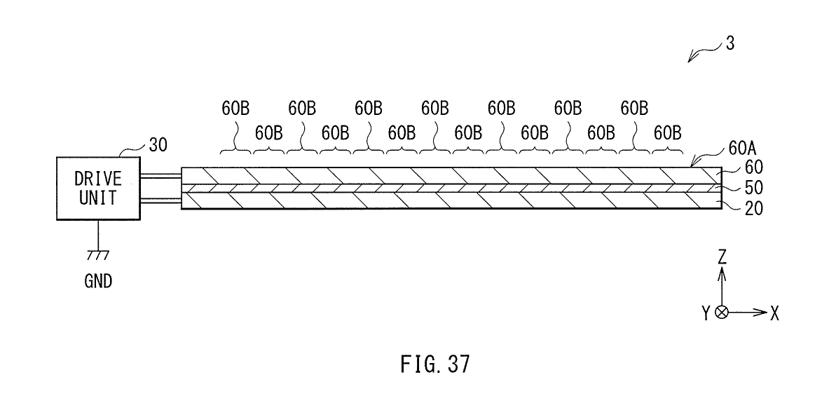

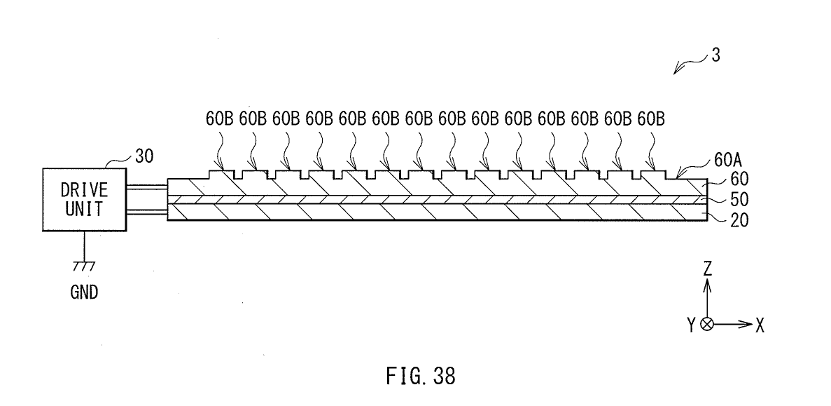

FIGS. 37 and 38 each illustrate an example of a cross-sectional configuration of an input apparatus 3 according to a third embodiment of the present application. The input apparatus 3 is equivalent to the above-described input apparatus 2 in which a plurality of key regions 60B are provided for the substrate 60 in the input apparatus 2. The input apparatus 3 serves as a keyboard apparatus.

The plurality of key regions 60B are arranged on the operation surface 60A. Each of the key regions 60B is equivalent to a key top to be pressed through operation by a user, and has a shape and size depending on the type of a key. In each of the key regions 60B, appropriate key display may be provided. In this key display, the type of a key, or the position (an outline) of each key, or both may be displayed. For the display, it is possible to adopt an appropriate printing technique. For example, screen printing, flexographic printing, or gravure printing may be adopted.

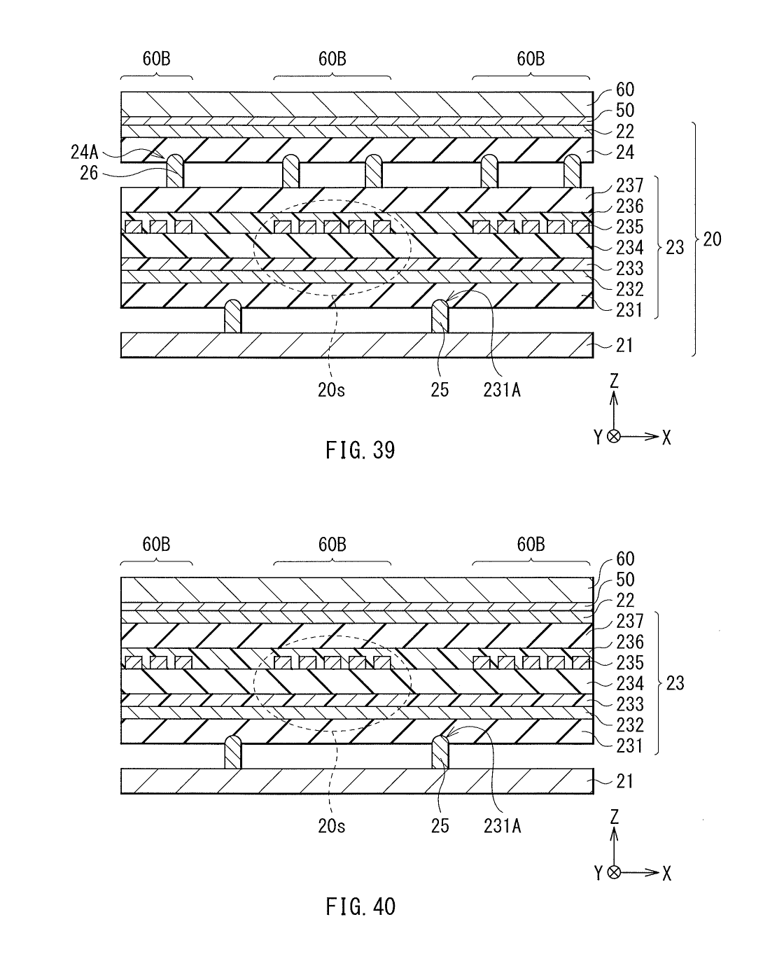

For example, the operation surface 60A may be configured of a flat surface as illustrated in FIG. 37, or may have a groove between the key regions 60B as illustrated in FIG. 38. For example, the key region 60B may be preferably arranged at a position facing the detection section 20s as illustrated in each of FIGS. 39 and 40.

Next, effects of the input apparatus 3 of the present embodiment will be described. In the present embodiment, the mitigation section is provided for the sensor device 20 in a manner similar to the above-described embodiments. Therefore, as compared with the above-described comparative example, it is possible to reduce the time from unloading to returning of each of the adhesion sections 25 and 26 (or the adhesion sections 25, 26, and 29) to the original shape. Accordingly, it is possible to reduce a decline in the response speed.

### 5. Variations on Sensor Device

[5.1 Magnetic-Type Sensor Device]

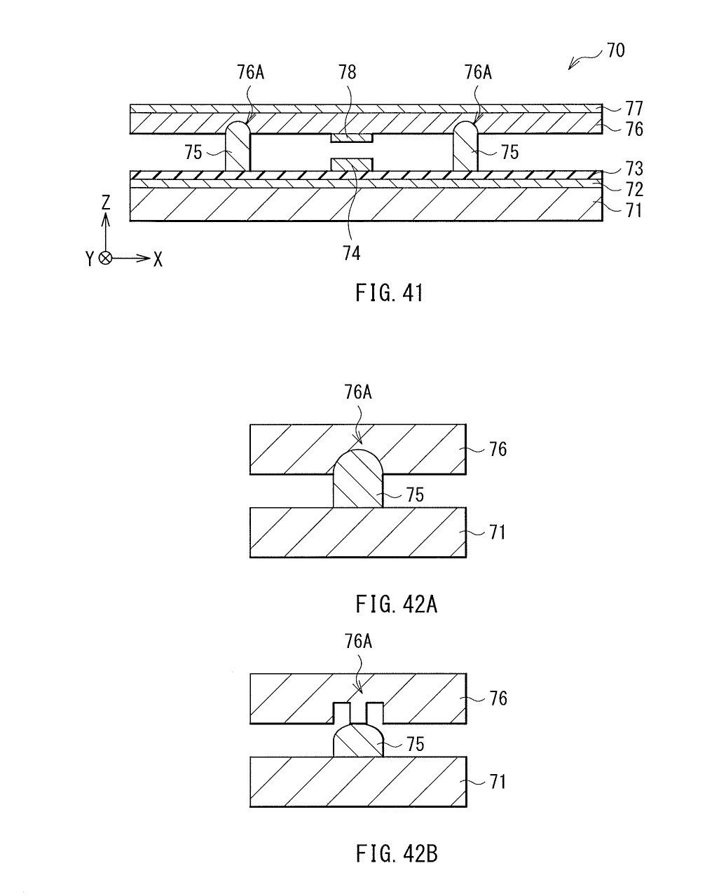

FIG. 41 illustrates an example of a cross-sectional configuration of a magnetic-type sensor device 70. The sensor device 70 is allowed to be used in place of the sensor device 20, in the display apparatus 1 according to the above-described first embodiment and modifications (Modifications 1 to 10), the input apparatus 2, and the input apparatus 3 each including the sensor device 20.

The sensor device 70 may include, for example, a shield layer 72 and an insulating layer 73 in this order on a substrate 71. The sensor device 70 may further include, for example, a plurality of giant magneto resistance (GMR) elements 74 and a plurality of adhesion sections 75. The GMR elements 74 may be two-dimensionally arranged on the surface of the insulating layer 73. The adhesion sections 75 may each be disposed at a position on the surface of the insulating layer 73 and in proximity to the GMR element 74. The sensor device 70 may further include, for example, a substrate 76, a shield layer 77, and a plurality of magnetic layers 78. The substrate 76 may be disposed to face the insulating layer 73 with a predetermined gap therebetween. The shield layer 77 may be disposed on a top surface of the substrate 76. The magnetic layers 78 may each be disposed on an undersurface of the substrate 76, at a position facing the GMR element 74.

The substrate 71 may be, for example, a glass substrate, a silicon substrate, or an alumina substrate. The shield layer 72 may be formed of, for example, permalloy. The insulating layer 73 may be formed of, for example, alumina or silicon oxide. The GMR element 74 may be an element in which electric resistance is changed by an external magnetic field generated by the magnetic layer 78. It is to be noted that a magnetoresistive effect element such as a tunnel magneto resistance (TMR) element may be provided in place of the GMR element 74.

The substrate 76 may be, for example, a silicon substrate. The shield layer 77 may be formed of, for example, permalloy. The magnetic layer 78 applies a magnetic field to the GMR element 74, and may be formed of, for example, an alloy such as a CoPt alloy and CoCrPt alloy. The adhesion section 75 is configured in a manner similar to that of the above-described adhesion section 25.

Each of the adhesion sections 75 is formed of an adhesive material having elasticity. Each of the adhesion sections 75 is in contact with the insulating layer 73 and the substrate 76. Of each of the adhesion sections 75, a top on the substrate 76 side is round, and may be shaped like, for example, a part of a sphere. For example, the shape of this top may be formed by a method similar to the method of forming the above-described adhesion section 25. The substrate 76 is shaped like a sheet, and has a depression 76A as a mitigation section, at a position facing each of the adhesion sections 75. Here, the mitigation section refers to a section having a function of mitigating an increase in an area where each of the adhesion sections 75 is in contact with the substrate 76. This area increases as the gap between the insulating layer 73 and the substrate 76 narrows.

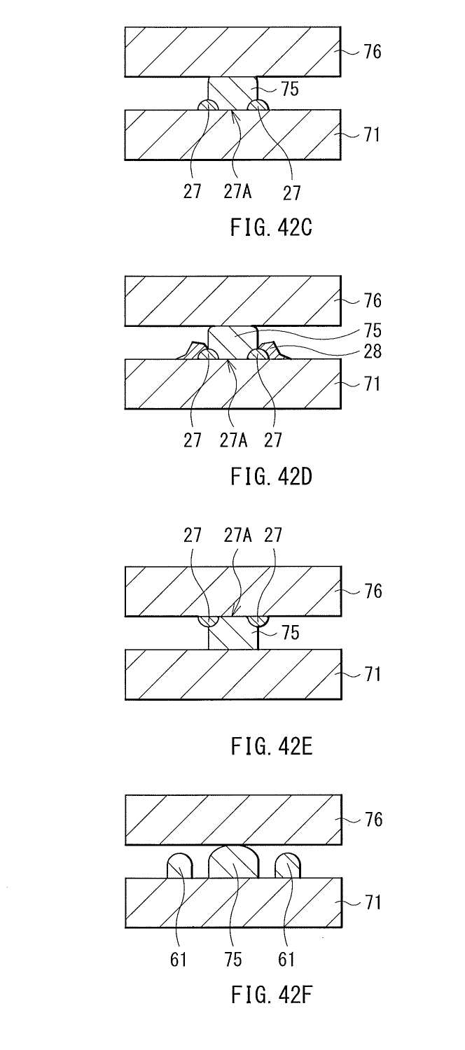

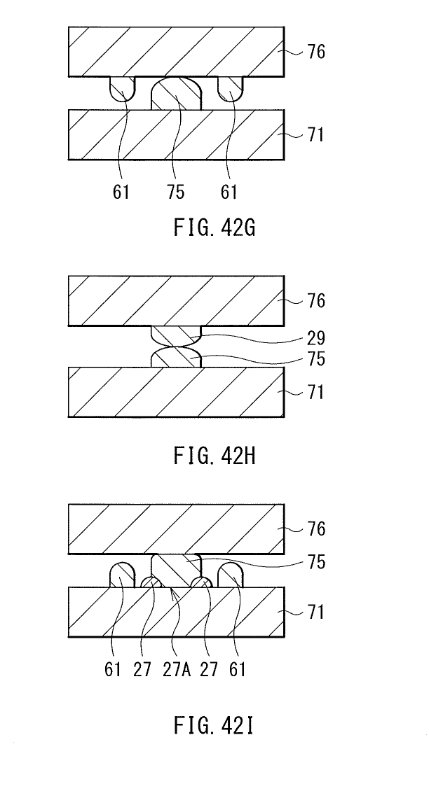

The depression 76A may be formed, for example, by selectively etching the silicon substrate. As illustrated in FIG. 42A, for example, the depression 76A may be round in a manner similar to that of the adhesion section 75, and may be shaped like, for example, a part of a sphere. Of the adhesion section 75, the top on the substrate 76 side is fitted into the depression 76A, and is in contact with an inner surface of the depression 76A. An entire round part of the top on the substrate 76 side may be preferably fitted into the depression 76A. In this case, an area of a contact part between the substrate 76 and the adhesion section 75 is substantially equal to an area of the inner surface of the depression 76A.

It is to be noted that the sensor device 70 may be, for example, configured as illustrated in each of FIGS. 42B to 42I. The adhesion section 75 and the substrate 76 illustrated in FIG. 42B are configured as with the adhesion section 25 and the insulating layer 231 illustrated in FIG. 16A, respectively. The adhesion section 75 and the substrate 76 illustrated in FIG. 42C are configured as with the adhesion section 25 and the insulating layer 231 illustrated in FIG. 18A, respectively. The adhesion section 75 and the substrate 76 illustrated in FIG. 42D are configured as with the adhesion section 25 and the insulating layer 231 illustrated in FIG. 23, respectively. The adhesion section 75 and the substrate 76 illustrated in in FIG. 42E are configured as with the adhesion section 25 and the insulating layer 231 illustrated in FIG. 25, respectively. The adhesion section 75 and the substrate 76 illustrated in FIG. 42F are configured as with the adhesion section 25 and the insulating layer 231 illustrated in FIG. 26A, respectively. The adhesion section 75 and the substrate 76 illustrated in FIG. 42G are configured as with the adhesion section 25 and the insulating layer 231 illustrated in FIG. 31, respectively. The adhesion section 75 and the substrate 76 illustrated in FIG. 42H are configured as with the adhesion section 25 and the insulating layer 231 illustrated in FIG. 32A, respectively. The adhesion section 75 and the substrate 76 illustrated in FIG. 42I are configured as with the adhesion section 25 and the insulating layer 231 illustrated in FIG. 34, respectively.

Next, effects of an apparatus including the sensor device 70 will be described. This apparatus is configured by providing the sensor device 70 in place of the sensor device 20, in the display apparatus 1 according to the above-described first embodiment and modifications (Modifications 1 to 10), the input apparatus 2, and the input apparatus 3 each including the sensor device 20. In the present embodiment, the mitigation section is provided for the sensor device 70 in a manner similar to the above-described embodiments. Therefore, as compared with the above-described comparative example, it is possible to reduce the time from unloading to returning of each of the adhesion sections 25 and 26 (or the adhesion sections 25, 26, and 29) to the original shape. Accordingly, it is possible to reduce a decline in the response speed.

[5.2 Resistance-Type Sensor Device]

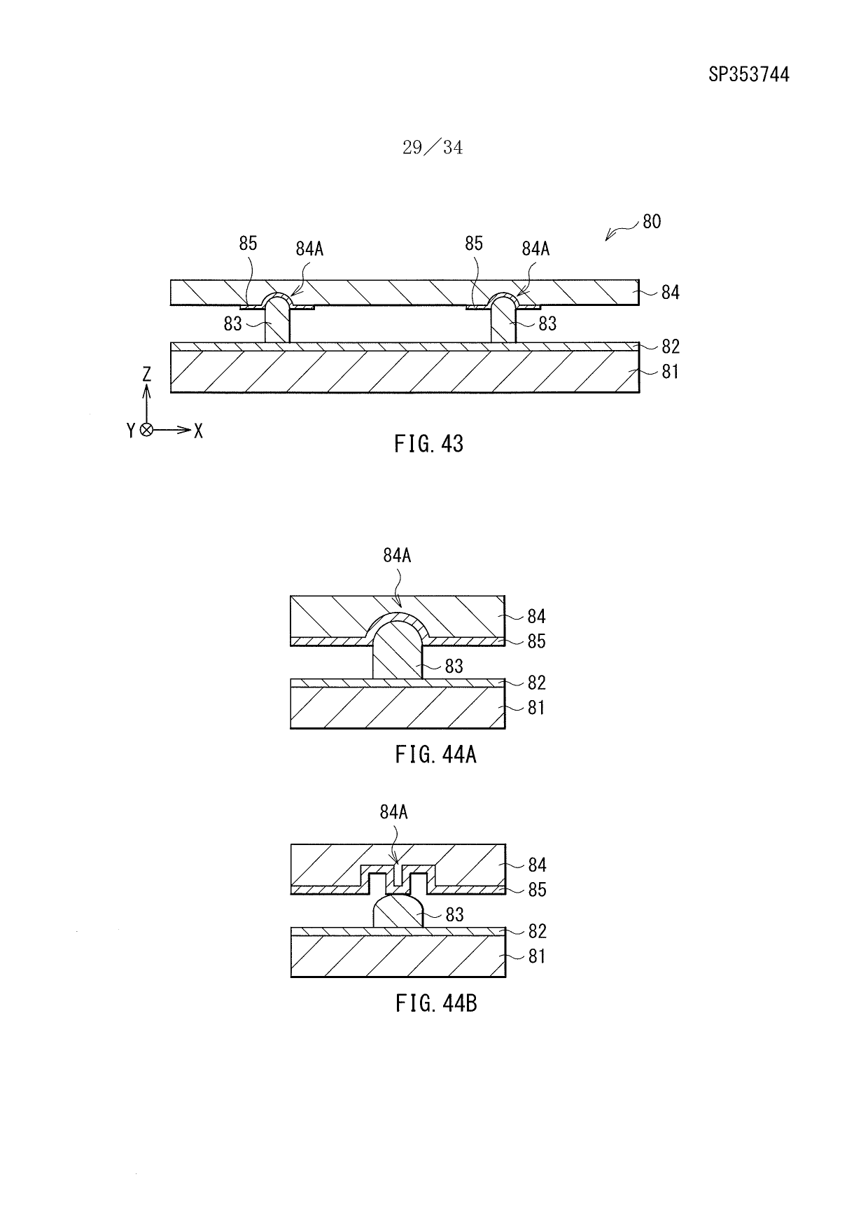

FIG. 43 illustrates an example of a cross-sectional configuration of a resistance-type sensor device 80. The sensor device 80 is allowed to be used in place of the sensor device 20, in the display apparatus 1 according to the above-described first embodiment and modifications (Modifications 1 to 10), the input apparatus 2, and the input apparatus 3 each including the sensor device 20.

The sensor device 80 may include, for example, a lower electrode 82 on a substrate 81. The sensor device 80 may further include, for example, a plurality of adhesion sections 83 arranged two-dimensionally on a surface of the lower electrode 82. The sensor device 80 may further include, for example, a substrate 84 and an upper electrode 85. The substrate 84 may be disposed to face the lower electrode 82 with a predetermined gap therebetween. The lower electrode 82 may be disposed on an undersurface of the substrate 84. The lower electrode 82 is equivalent to a specific but not limitative example of “first wiring” according to one embodiment of the present application. The upper electrode 85 is equivalent to a specific but not limitative example of “second wiring” according to one embodiment of the present application.

The substrate 81 may be, for example, a glass substrate or a resin substrate. The lower electrode 82 and the upper electrode 85 may be each formed of, for example, a metallic material such as Al and Cu.

Each of the adhesion sections 83 is formed of an adhesive material having elasticity and conductivity. Each of the adhesion sections 83 is in contact with the lower electrode 82 and the upper electrode 85. Of each of the adhesion sections 83, a top on the substrate 84 side is round, and may be shaped like, for example, a part of a sphere. For example, the shape of this top may be formed by a method similar to the method of forming the above-described adhesion section 25. The substrate 84 is shaped like a sheet, and has a depression 84A as a mitigation section, at a position facing each of the adhesion sections 83. Here, the mitigation section refers to a section having a function of mitigating an increase in an area where each of the adhesion sections 83 is in contact with the upper electrode 85. This area increases as the gap between the lower electrode 82 and the upper electrode 85 narrows.

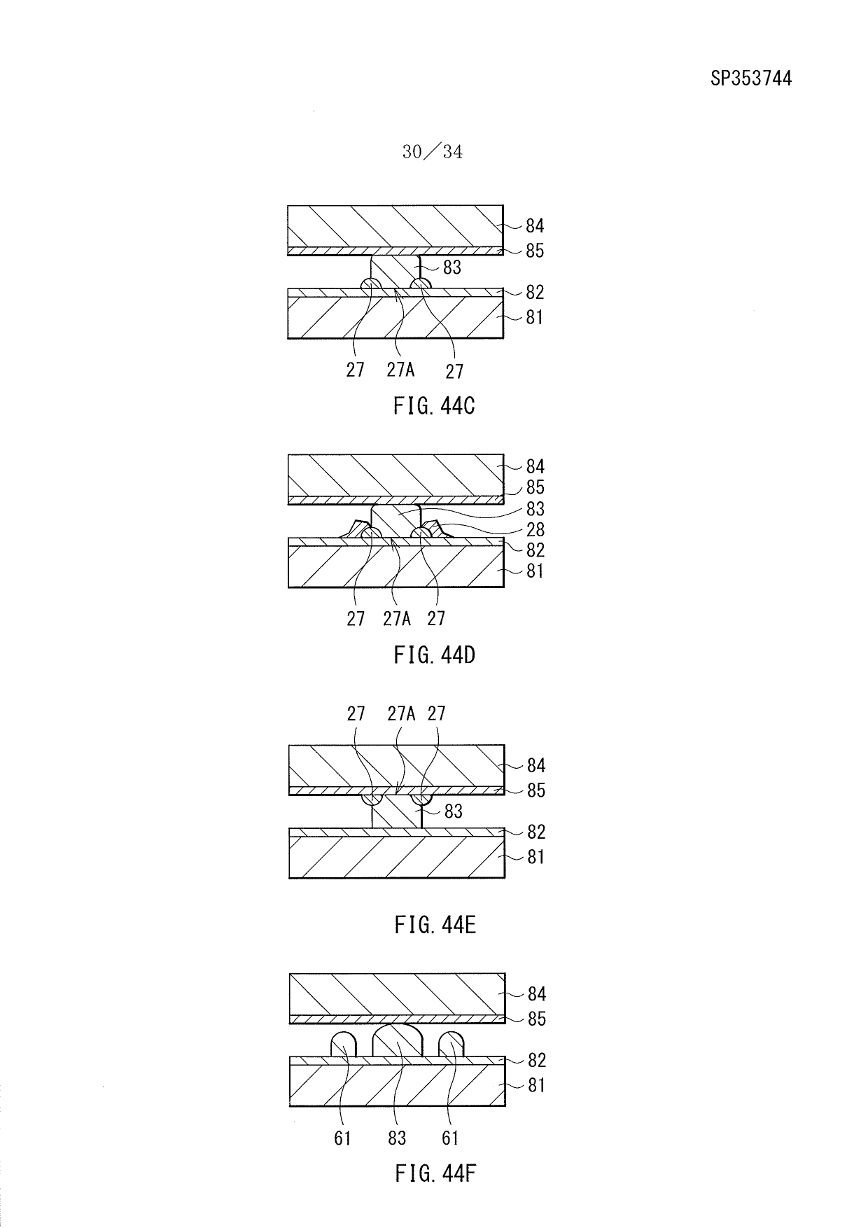

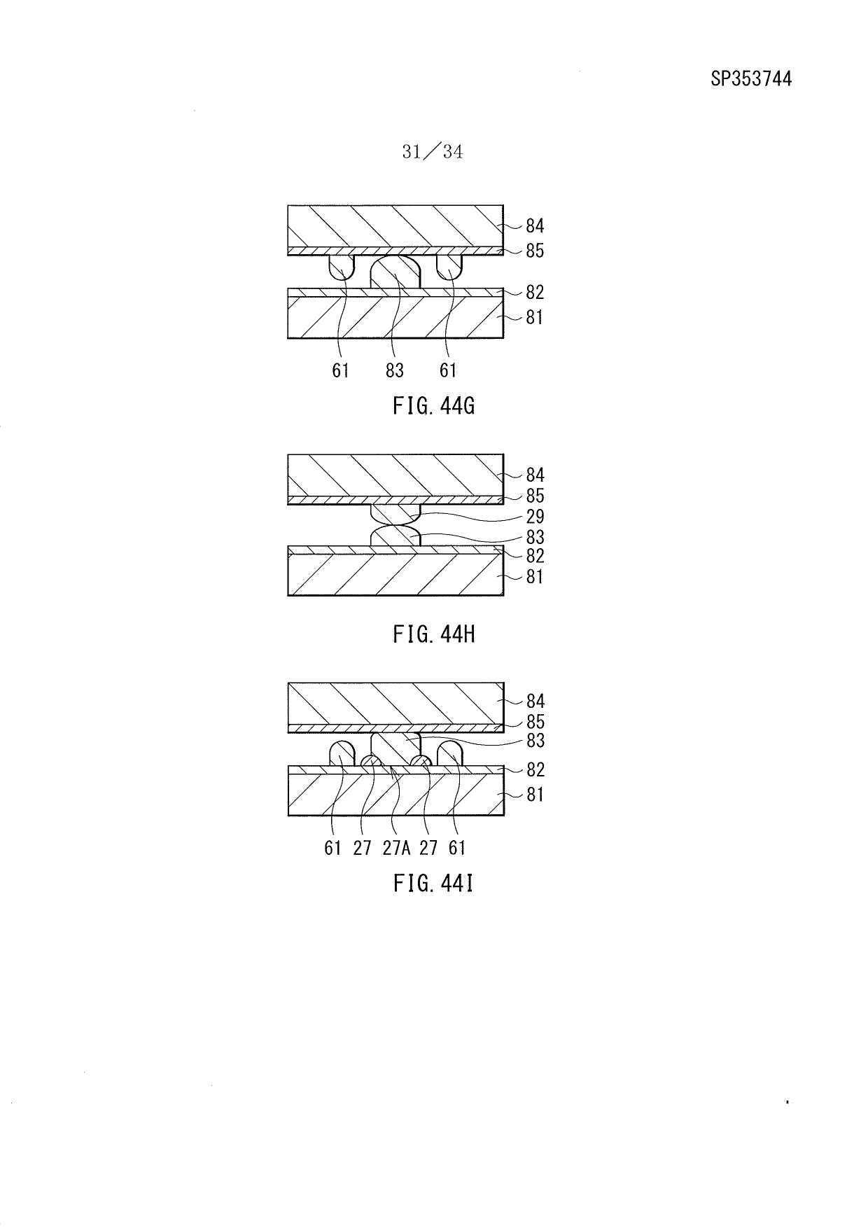

The depression 84A may be, for example, formed by transferring the shape of a mold to a resin film. As illustrated in FIG. 44A, for example, as with the adhesion section 83, the depression 84A may be round, and may be shaped like, for example, a part of a sphere. Of the adhesion section 83, the top on the substrate 84 side is fitted into the depression 84A and is in contact with an inner surface of the depression 84A. An entire round part of the top on the insulating layer 231 side may be preferably fitted into the depression 84A. In this case, an area of a contact part between the upper electrode 85 and the adhesion section 83 is substantially equal to an area of the inner surface of the depression 84A.

It is to be noted that the sensor device 80 may be, for example, configured as illustrated in each of FIGS. 44B to 44I. The adhesion section 83 and the substrate 84 illustrated in FIG. 44B are configured as with the adhesion section 25 and the insulating layer 231 illustrated in FIG. 16A, respectively. The adhesion section 83 and the substrate 84 illustrated in FIG. 44C are configured as with the adhesion section 25 and the insulating layer 231 illustrated in FIG. 18A, respectively. The adhesion section 83 and the substrate 84 illustrated in FIG. 44D are configured as with the adhesion section 25 and the insulating layer 231 illustrated in FIG. 23, respectively. The adhesion section 83 and the substrate 84 illustrated in FIG. 44E are configured as with the adhesion section 25 and the insulating layer 231 illustrated in FIG. 25, respectively. The adhesion section 83 and the substrate 84 illustrated in FIG. 44F are configured as with the adhesion section 25 and the insulating layer 231 illustrated in FIG. 26A, respectively. The adhesion section 83 and the substrate 84 illustrated in FIG. 44G are configured as with the adhesion section 25 and the insulating layer 231 illustrated in FIG. 31, respectively. The adhesion section 83 and the substrate 84 illustrated in FIG. 44H are configured as with the adhesion section 25 and the insulating layer 231 illustrated in FIG. 32A, respectively. The adhesion section 83 and the substrate 84 illustrated in FIG. 44I are configured as with the adhesion section 25 and the insulating layer 231 illustrated in FIG. 34, respectively.

Next, effects of an apparatus including the sensor device 80 will be described. This apparatus is configured by providing the sensor device 80 in place of the sensor device 20, in the display apparatus 1 according to the above-described first embodiment and modifications (Modifications 1 to 10), the input apparatus 2, and the input apparatus 3 each including the sensor device 20. In the present embodiment, the mitigation section is provided for the sensor device 80 in a manner similar to the above-described embodiments. Therefore, as compared with the above-described comparative example, it is possible to reduce the time from unloading to returning of each of the adhesion sections 25 and 26 (or the adhesion sections 25, 26, and 29) to the original shape. Accordingly, it is possible to reduce a decline in the response speed.

### 6. Fourth Embodiment

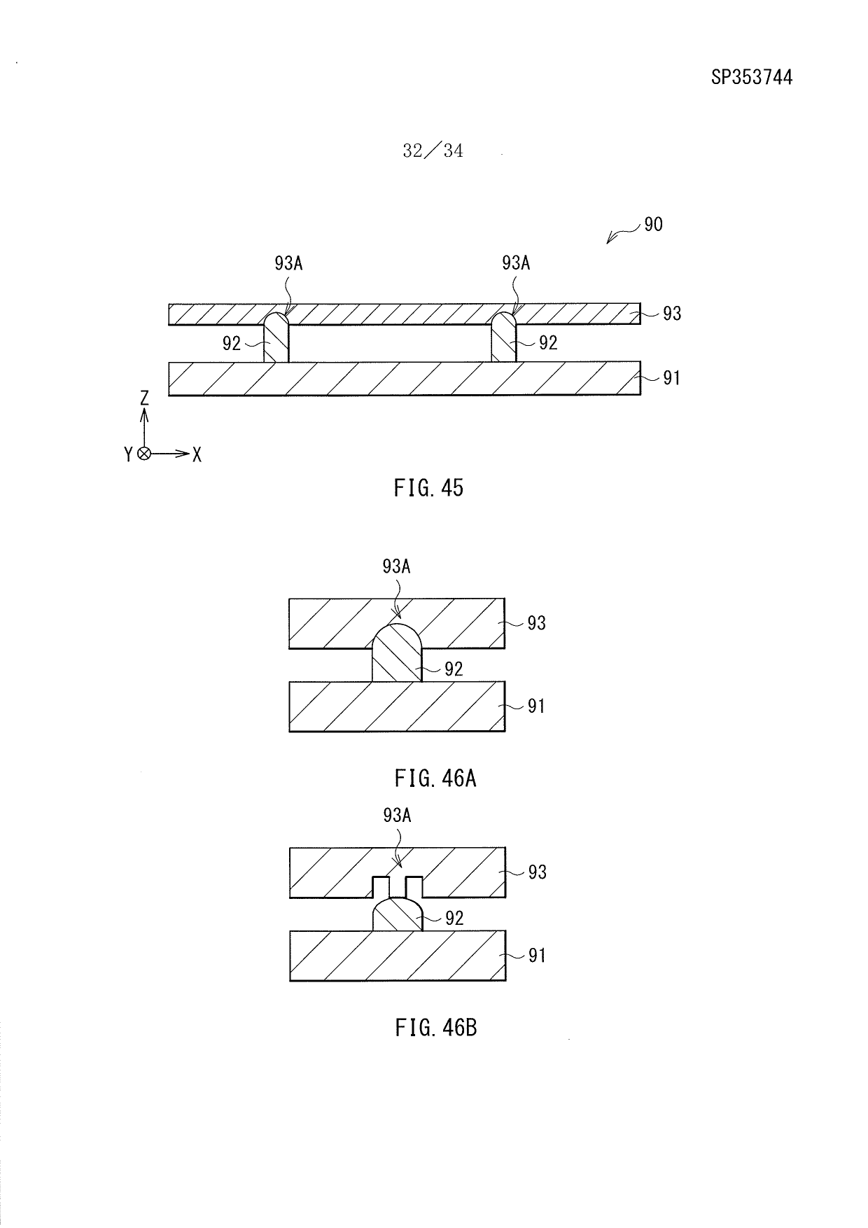

Next, FIG. 45 illustrates an example of a cross-sectional configuration of a passive device 90 according to a fourth embodiment. The passive device 90 may include, for example, a substrate 91, a plurality of adhesion sections 92, and a substrate 93. The adhesion sections 92 may be two-dimensionally arranged on a surface of the substrate 91. The substrate 93 may be disposed to face the substrate 91 with a predetermined gap therebetween.

For example, the substrates 91 and 93 may each be a glass substrate or a resin substrate. Each of the adhesion sections 92 is formed of an adhesive material having elasticity. Each of the adhesion sections 92 is in contact with the substrates 91 and 93. Of each of the adhesion sections 92, a top on the substrate 93 side is round, and may be shaped like, for example, a part of a sphere. For example, the shape of this top may be formed by a method similar to the method of forming the above-described adhesion section 25. The substrate 93 is shaped like a sheet, and has a depression 93A as a mitigation section, at a position facing each of the adhesion sections 92. Here, the mitigation section refers to a section having a function of mitigating an increase in an area where each of the adhesion sections 92 is in contact with the substrate 93. This area increases as the gap between the substrates 91 and 93 narrows.

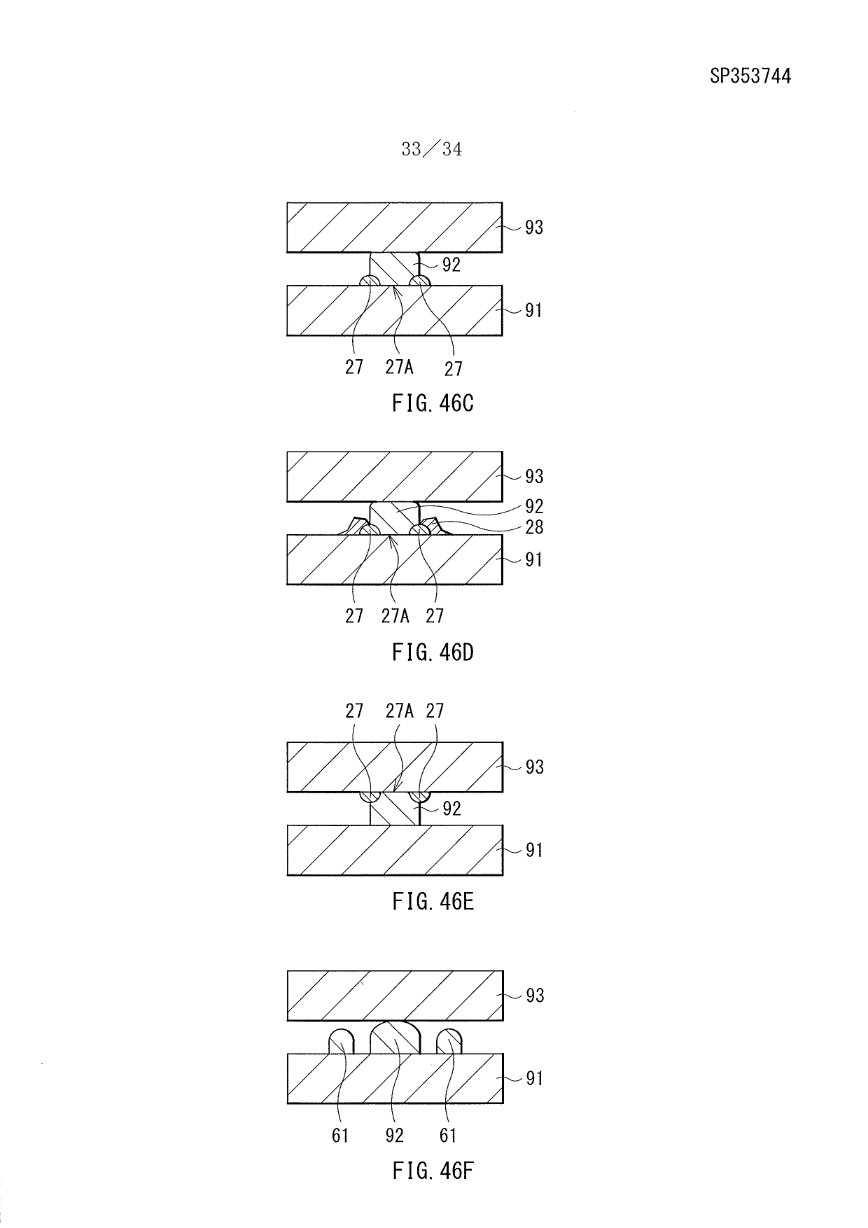

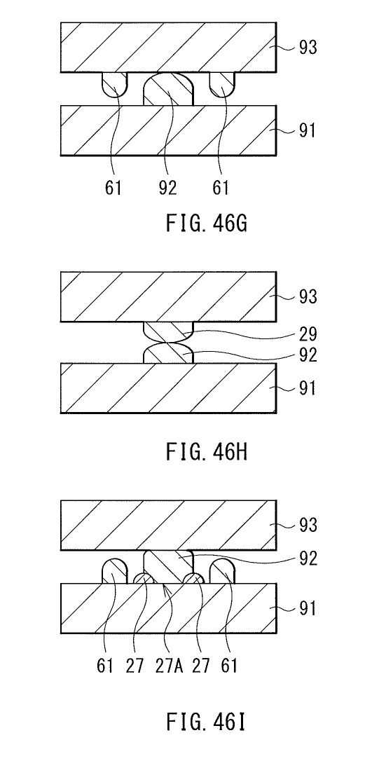

The depression 93A may be, for example, formed by transferring the shape of a mold to a resin film. As illustrated in FIG. 46A, for example, as with the adhesion section 92, the depression 93A is round, and may be shaped like, for example, a part of a sphere. Of the adhesion section 92, the top on the substrate 93 side is fitted into the depression 93A and is in contact with an inner surface of the depression 93A. An entire round part of the top on the substrate 93 side may be preferably fitted into the depression 93A. In this case, an area of a contact part between the substrate 93 and the adhesion section 92 is substantially equal to an area of the inner surface of the depression 93A.

It is to be noted that, for example, the passive device 90 may be configured as illustrated in each of FIGS. 46B to 46I. The adhesion section 92 and the substrate 93 illustrated in FIG. 46B are configured as with the adhesion section 25 and the insulating layer 231 illustrated in FIG. 16A, respectively. The adhesion section 92 and the substrate 93 illustrated in FIG. 46C are configured as with the adhesion section 25 and the insulating layer 231 illustrated in FIG. 18A, respectively. The adhesion section 92 and the substrate 93 illustrated in FIG. 46D are configured as with the adhesion section 25 and the insulating layer 231 illustrated in FIG. 23, respectively. The adhesion section 92 and the substrate 93 illustrated in FIG. 46E are configured as with the adhesion section 25 and the insulating layer 231 illustrated in FIG. 25, respectively. The adhesion section 92 and the substrate 93 illustrated in FIG. 46F are configured as with the adhesion section 25 and the insulating layer 231 illustrated in FIG. 26A, respectively. The adhesion section 92 and the substrate 93 illustrated in FIG. 46G are configured as with the adhesion section 25 and the insulating layer 231 illustrated in FIG. 31, respectively. The adhesion section 92 and the substrate 93 illustrated in FIG. 46H are configured as with the adhesion section 25 and the insulating layer 231 illustrated in FIG. 32A, respectively. The adhesion section 92 and the substrate 93 illustrated in FIG. 46I are configured as with the adhesion section 25 and the insulating layer 231 illustrated in FIG. 34, respectively.

Next, effects of the passive device 90 will be described. In the present embodiment, the mitigation section is provided for the passive device 90 in a manner similar to that in each of the above-described embodiments. Therefore, as compared with the above-described comparative example, it is possible to reduce the time from unloading to returning of each of the adhesion sections 25 and 26 (or the adhesion sections 25, 26, and 29) to the original shape. Accordingly, it is possible to reduce a decline in the response speed.

The present application has been described above with reference to some embodiments and modifications, but is not limited thereto and may be variously modified. It is to be noted that the effects described in the present specification are mere examples. Effects of the present application are not limited to those described in the present specification. The present application may have effects other than the effects described in the present specification.

It is possible to achieve at least the following configurations from the above-described example embodiments of the disclosure.

(1) A sensor device including:

a first base material and a second base material disposed apart to face each other;

a plurality of first adhesion sections that are two-dimensionally arranged in a gap between the first base material and the second base material and have elasticity; and

a mitigation section configured to mitigate an increase in contact area of each of the first adhesion sections to one of the first base material and the second base material, the contact area increasing as the gap narrows.

(2) The sensor device according to (1), wherein

each of the first adhesion sections is in contact with the first base material and the second base material,

a top on a second base material side of each of the first adhesion sections is round, and

the second base material has a depression serving as the mitigation section, at positions facing the respective first adhesion sections.

(3) The sensor device according to (2), wherein an inner surface of the depression is round.

(4) The sensor device according to (2), wherein the depression is annular.

(5) The sensor device according to any one of (1) to (4), wherein each of the first adhesion sections is formed by printing on a surface of the first base material.

(6) The sensor device according to (1), wherein

each of the first adhesion sections is in contact with the first base material and the second base material,

the mitigation section is a plurality of convex annular bodies each provided on a surface of one of the first base material and the second base material, for each of the first adhesion sections, and

each of the first adhesion sections is in contact with the surface of the first base material or the second base material, through an opening of the convex annular body, as well as in contact with the convex annular body.

(7) The sensor device according to (6), wherein each of the first adhesion sections and each of the convex annular bodies are formed by printing on the surface of one of the first base material and the second base material.

(8) The sensor device according to (1), wherein

each of the first adhesion sections is in contact with the first base material and the second base material,

the mitigation section is a plurality of projections each provided at a position on a surface of one of the first base material and the second base material, without being in contact with each of the first adhesion sections, and

each of the projections is in contact with only one of the first base material and the second base material, when external force narrowing the projection is applied to neither the first base material nor the second base material.

(9) The sensor device according to (8), wherein each of the first adhesion sections and each of the projections are formed by printing on the surface of one of the first base material and the second base material.

(10) The sensor device according to (1), wherein

each of the first adhesion sections is in contact with the first base material, and

the mitigation section is a plurality of second adhesion sections disposed between the second base material and each of the first adhesion sections and having elasticity.

(11) The sensor device according to (10), wherein

each of the first adhesion sections is formed by printing on a surface of the first base material, and

each of the second adhesion sections is formed by printing on a surface of the second base material.

(12) The sensor device according to any one of (1) to (11), wherein

the first base material is a first conductive layer, or a layer including the first conductive layer, and

the second base material is a second conductive layer electrically separated from the first conductive layer, or a layer including the second conductive layer.

(13) The sensor device according to any one of (1) to (11), wherein

each of the first adhesion sections has conductivity,

the first base material has a plurality of first wirings electrically connected to the plurality of first adhesion sections, and

the second base material has a plurality of second wirings electrically connected to the plurality of first adhesion sections.

(14) The sensor device according to any one of (1) to (11), wherein

the first base material includes a plurality of magnetoresistive effect elements two-dimensionally arranged, and

the second base material includes a plurality of magnetic layers each disposed at a position facing each of the magnetoresistance effect elements.

(15) A display apparatus including:

a display panel having a display surface; and

a sensor device disposed on a side, opposite to the display surface, of the display panel,

wherein the sensor device includes

a first base material and a second base material disposed apart to face each other,

a plurality of first adhesion sections that are two-dimensionally arranged in a gap between the first base material and the second base material and have elasticity, and

a mitigation section configured to mitigate an increase in contact area of each of the first adhesion sections to one of the first base material and the second base material, the contact area increasing as the gap narrows.

(16) An input apparatus including:

a substrate having an operation surface; and

a sensor device disposed on a side, which is opposite to the operation surface, of the substrate,

wherein the sensor device includes

a first base material and a second base material disposed apart to face each other,

a plurality of first adhesion sections that are two-dimensionally arranged in a gap between the first base material and the second base material and have elasticity, and

a mitigation section configured to mitigate an increase in contact area of each of the first adhesion sections to one of the first base material and the second base material, the contact area increasing as the gap narrows.

(17) A method of manufacturing a sensor device, the method including:

increasing viscosity of each of a plurality of first adhesion sections, after printing, on a surface of a first base material, the first adhesion sections that are two-dimensionally arranged;

providing a mitigation section on a surface of the first base material or a second base material, the mitigation section being configured to mitigate an increase in contact area of each of the first adhesion sections to one of the first base material and the second base material, the contact area increasing as a gap between the first base material and the second base material narrows, when the first base material and the second base material are adhered to each other, with each of the first adhesion sections interposed therebetween; and

adhering the first base material and the second base material to each other, with each of the first adhesion sections interposed therebetween.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A sensor device comprising:
a first base material and a second base material disposed apart to face each other;
a plurality of first adhesion sections that are two-dimensionally arranged in a gap between the first base material and the second base material and have elasticity; and
a mitigation section configured to mitigate an increase in contact area of each of the first adhesion sections to one of the first base material and the second base material, the contact area increasing as the gap narrows.

2. The sensor device according to claim 1, wherein
each of the first adhesion sections is in contact with the first base material and the second base material,
a top on a second base material side of each of the first adhesion sections is round, and
the second base material has a depression serving as the mitigation section, at positions facing the respective first adhesion sections.

3. The sensor device according to claim 2, wherein an inner surface of the depression is round.

4. The sensor device according to claim 2, wherein the depression is annular.

5. The sensor device according to claim 2, wherein each of the first adhesion sections is formed by printing on a surface of the first base material.

6. The sensor device according to claim 1, wherein
each of the first adhesion sections is in contact with the first base material and the second base material,
the mitigation section is a plurality of convex annular bodies each provided on a surface of one of the first base material and the second base material, for each of the first adhesion sections, and
each of the first adhesion sections is in contact with the surface of the first base material or the second base material, through an opening of the convex annular body, as well as in contact with the convex annular body.

7. The sensor device according to claim 6, wherein each of the first adhesion sections and each of the convex annular bodies are formed by printing on the surface of one of the first base material and the second base material.

8. The sensor device according to claim 1, wherein
each of the first adhesion sections is in contact with the first base material and the second base material,
the mitigation section is a plurality of projections each provided at a position on a surface of one of the first base material and the second base material, without being in contact with each of the first adhesion sections, and
each of the projections is in contact with only one of the first base material and the second base material, when external force narrowing the projection is applied to neither the first base material nor the second base material.

9. The sensor device according to claim 8, wherein each of the first adhesion sections and each of the projections are formed by printing on the surface of one of the first base material and the second base material.

10. The sensor device according to claim 1, wherein
each of the first adhesion sections is in contact with the first base material, and
the mitigation section is a plurality of second adhesion sections disposed between the second base material and each of the first adhesion sections and having elasticity.

11. The sensor device according to claim 10, wherein
each of the first adhesion sections is formed by printing on a surface of the first base material, and
each of the second adhesion sections is formed by printing on a surface of the second base material.

12. The sensor device according to claim 1, wherein
the first base material is a first conductive layer, or a layer including the first conductive layer, and
the second base material is a second conductive layer electrically separated from the first conductive layer, or a layer including the second conductive layer.

13. The sensor device according to claim 1, wherein
each of the first adhesion sections has conductivity,
the first base material has a plurality of first wirings electrically connected to the plurality of first adhesion sections, and
the second base material has a plurality of second wirings electrically connected to the plurality of first adhesion sections.

14. The sensor device according to claim 1, wherein
the first base material includes a plurality of magnetoresistive effect elements two-dimensionally arranged, and
the second base material includes a plurality of magnetic layers each disposed at a position facing each of the magnetoresistance effect elements.

15. A display apparatus comprising:
a display panel having a display surface; and
a sensor device disposed on a side, opposite to the display surface, of the display panel,
wherein the sensor device includes
a first base material and a second base material disposed apart to face each other,
a plurality of first adhesion sections that are two-dimensionally arranged in a gap between the first base material and the second base material and have elasticity, and
a mitigation section configured to mitigate an increase in contact area of each of the first adhesion sections to one of the first base material and the second base material, the contact area increasing as the gap narrows.

16. An input apparatus comprising:
a substrate having an operation surface; and
a sensor device disposed on a side, which is opposite to the operation surface, of the substrate,
wherein the sensor device includes
a first base material and a second base material disposed apart to face each other,
a plurality of first adhesion sections that are two-dimensionally arranged in a gap between the first base material and the second base material and have elasticity, and
a mitigation section configured to mitigate an increase in contact area of each of the first adhesion sections to one of the first base material and the second base material, the contact area increasing as the gap narrows.

17. A method of manufacturing a sensor device, the method comprising:
increasing viscosity of each of a plurality of first adhesion sections, after printing, on a surface of a first base material, the first adhesion sections that are two-dimensionally arranged;
providing a mitigation section on a surface of the first base material or a second base material, the mitigation section being configured to mitigate an increase in contact area of each of the first adhesion sections to one of the first base material and the second base material, the contact area increasing as a gap between the first base material and the second base material narrows, when the first base material and the second base material are adhered to each other, with each of the first adhesion sections interposed therebetween; and
adhering the first base material and the second base material to each other, with each of the first adhesion sections interposed therebetween.
